(19) United States
(12) Patent Application Publication
(10) Pub. No.: US 2015/0221865 A1
(43) Pub. Date: Aug. 6, 2015

(54) VARIABLE RESISTANCE ELEMENT AND METHOD FOR PRODUCING VARIABLE RESISTANCE ELEMENT

(71) Applicant: NEC CORPORATION, Tokyo (JP)

(72) Inventors: Munehiro Tada, Tokyo (JP); Noriyuki Iguchi, Tokyo (JP); Naoki Banno, Tokyo (JP); Koichiro Okamoto, Tokyo (JP)

(73) Assignee: NEC CORPORATION, Tokyo (JP)

(21) Appl. No.: 14/419,520

(22) PCT Filed: Apr. 26, 2013
(86) PCT No.: PCT/JP2013/062399

§ 371 Date: Feb. 4, 2015

(30) Foreign Application Priority Data
Aug. 20, 2012 (JP) 2012-181724

(51) Int. Cl. H01L 45/00

(52) U.S. Cl. CPC H01L 45/122; H01L 45/1253; H01L 45/145

(57) ABSTRACT

The present invention provides a highly reliable resistance changing element while maintaining a low parasitic capacitance of the wiring when the resistance changing element is provided in the wiring layer on a semiconductor substrate. In the present invention, there is selected, as a structure for providing the resistance changing element in the wiring layer on a semiconductor substrate, a structure having: a first interlayer insulation film and a second interlayer insulation film positioned above the first interlayer insulation film; and a resistance changing element formed on the first interlayer insulation film and provided with at least an electrode and a resistance changing film; a protective insulation film being formed on the side surface of the resistance changing element, and the first and second interlayer insulation films being in direct contact with each other.

### TECHNICAL FIELD

The present invention relates to a variable resistance non-volatile switching element (hereinafter referred to as a “variable resistance element”) and a method for producing the same. More specifically, the present invention relates to a variable resistance element provided inside a multi-layered wiring layer, a memory including a variable resistance element provided inside the multi-layered wiring layer, a semiconductor device incorporating a field programmable gate array (FPGA) using a variable resistance element provided inside a multi-layered wiring layer, and a method for producing a variable resistance element inside a multi-layered wiring layer.

### BACKGROUND ART

Semiconductor devices including silicon devices have been more highly integrated to achieve lower power consumption through miniaturization following the scaling law known as “Moore's Law”. Highly integrated devices have been developed so far at the pace of increasing the number of transistors in the devices four times every three years. In recent years, the gate length Lg of a MOSFET (Metal Oxide Semiconductor Field Effect Transistor) is 20 nm or smaller. Because of rising costs for lithography processes and the physical limits of device scaling, higher integration and lower power consumption require another approach beside the miniaturization following the scaling law. In other words, there has been need for improvement in the performance of highly integrated devices through an approach other than the miniaturization following the scaling law.

Increasing costs for lithography processes are caused by rising prices of manufacturing apparatuses and mask sets. The physical limits of device scaling are determined by operational limits attributed to the miniaturization of device scales and by scale variation limits.

Use of “back-end devices” has been expected in recent years to serve as an approach for improving device performance independently of the “miniaturization following the scaling law”. A “back-end device” is an active device mounted in a multi-layered wiring layer in a ULSI. In particular, examples of storage devices using low power consuming, non-volatile variable resistance switching elements include MRAMs (magnetic random access memories), PRAMs (phase-change random access memories), ReRAMs (resistive random access memories), or the like.

“Back-end devices” including variable resistance switching elements and mounted on conventional CMOS semiconductor devices are expected to serve as non-volatile memories and non-volatile switches that can reduce power required for maintaining the states of the memories and switches and reduce the power consumption of semiconductor devices.

“Back-end devices”, for example, non-volatile memories including variable resistance elements such as MRAMs, PRAMs, and ReRAMs, are expected to increase the on-board capacity along the need for smaller and higher-capacity semiconductor devices.

A rewritable programmable logic device called “FPGA” is a “logic device” categorized as an intermediate between “gate arrays” and “standard cells”. An FPGA performs “switching of switching elements” after the manufacturing of a “logic device” chip, allowing users to select desirable circuit configurations. The “switching of logic circuits” in the FPGA is expected to be performed using variable resistance elements mounted in a multi-layered wiring layer as variable resistance non-volatile switching elements. By configuring an FPGA with variable resistance elements that can be mounted in a multi-layered wiring layer, lower power consumption can be achieved with a higher degree of flexibility in circuit layout.

As a variable resistance non-volatile switching element (a variable resistance element) suitable for the use of “switching of logic circuits” in FPGAs, a variable resistance element using an ion conductor that forms a ReRAM, that is, NanoBridge (registered trademark of NEC Corporation) is known. The ion conductor used in the variable resistance element is a solid electrolyte in which ions can move freely under an electric field applied.

The following describes the operation principles of variable resistance switching elements used in MRAMs, PRAMs, and ReRAMs, which are storage devices using non-volatile variable resistance switching elements. FIG. 14, FIG. 15, and FIG. 17 respectively illustrate an example of the configuration of an MRAM, a PRAM, and a ReRAM. In addition, FIG. 16 illustrates an example of the configuration of an FRAM (ferroelectric RAM).

The MRAM uses the phenomenon of magnetization generated in a ferromagnetic body by a magnetic field applied externally and remaining in the ferromagnetic body even after the external magnetic field is removed. MRAM cells have a configuration in which two magnetic layers are stacked with an insulator therebetween. Of the two ferromagnetic layers, the magnetization direction of one magnetic layer (fixed layer) serves as a reference magnetization direction, and the magnetization direction of the other magnetic layer (free layer) is changed in accordance with stored data. Depending on the matching between the magnetization directions of the ferromagnetic layers, magnetic resistance varies. Data is stored by using the fact that the amount of current flowing through the storage element varies depending on the magnetic resistance.

To write data, in accordance with data to be stored, the magnetization direction of the magnetic layer (free layer) for data storage is set, and the direction of the magnetic field applied externally to the magnetic layers (free layer) for data storage is determined.

As a method for writing data in MRAM cells, there is a method for passing electric current through a “write wiring” provided separately from memory cells and applying a magnetic field generated by the electric current flowing through the “write wiring” to the magnetic layer (free layer) for data storage. By inverting the direction of the electric current flowing through the “write wiring”, the direction of the generated magnetic field is inverted, which can in turn invert the magnetization direction of the magnetic layer (free layer) for data storage. This method using the magnetic field generated by the electric current flowing through the “write wiring” is referred to as an electric-current-magnetic-field write method.

Another method, “spin-injected magnetization inversion”, is also used that inverts the magnetization direction of a magnetization free layer (free layer) by spin torque injected from a magnetization invariable layer (fixed layer) by passing electric current directly in the stacked structure of two magnetic layers with an insulator film therebetween.

The PRAM uses the phenomenon of a change in resistance values as a phase-change material is turned into the crystalline state (low resistance) or the amorphous state (high resistance) by electric current applied externally. PRAM cells have a configuration including two electrodes with a phase-change layer therebetween. Depending on the difference in the crystalline and amorphous phases of the “variable resistance element film” composed of the phase-change material, resistivity largely varies. Data is stored by using the fact that the amount of current flowing through the storage element varies depending on the difference in resistivity between the crystalline and amorphous phases. To write data, in accordance with data to be stored, the current value and pulse width are determined for causing the phase change from the “low-resistance crystalline state” to the “high-resistance amorphous state” or the phase change from the “high-resistance amorphous state” to the “low-resistance crystalline state”, whereby any of the “low-resistance crystalline state” and the “high-resistance amorphous state” is set.

Examples of typical phase-change materials include chalcogenide alloys, which are represented by a chalcogenide alloy (Ge₂Sb₂Te₅) composed of germanium, antimony, and tellurium, and the phase-change materials (Ge₂Sb₂Te₅) generally referred to as “GST”.

When GST in the “low-resistance crystalline state” is heated to higher temperature more than 600° C., it loses its crystalline form. When GST is cooled thereafter, its phase is changed to the “high-resistance amorphous state”. By contrast, when GST in the “high-resistance amorphous state” is heated to its crystallization temperature or higher but below its dissolving point and the heated state is maintained, “crystallization” advances again and GST returns to the “low-resistance crystalline state”.

As for the PRAM, the phase-change material (GST) in the “low-resistance crystalline state” represents “1”, which is referred to as the “set state”, while the phase-change material (GST) in the “high-resistance amorphous state” represents “0”, which is referred to as the “reset state”.

To cause a shift from the “reset state” to the “set state”, in other words, to cause the phase change from the “high-resistance amorphous state” to the “low-resistance crystalline state”, a relatively small amount of electric current as a set programming current pulse is passed for a long period of time. Since the “high-resistance amorphous state” represents a large resistance value, even a “small amount of electric current” can generate sufficient Joule's heat for heating GST to its crystallization temperature or higher, whereby the heated state is maintained, “crystallization” advances again, and GST returns to the “low-resistance crystalline state”.

To cause a shift from the “set state” to the “reset state”, in other words, to cause the phase change from the “low-resistance crystalline state” to the “high-resistance amorphous state”, a relatively large amount of electric current as a reset programming current pulse is passed for a short period of time. Since the “low-resistance crystalline state” represents a small resistance value, passing a “large amount of electric current” can generate sufficient Joule's heat for heating GST to higher temperature more than 600° C. When GST reaches the higher temperature more than 600° C., the phase change to the “high-resistance amorphous state” advances, and the resistance value rises sharply. To prevent an abrupt rise in the generated Joule's heat, the width of the current pulse is set to a short period of time.

To write data in the PRAM, by applying the set programming current pulse or the reset programming current pulse to the storage element, the shift from the “reset state” to the “set state” and the shift from the “set state” to the “restate state” are made reversibly.

The ReRAM uses the phenomenon of a change in resistance values as a conductive path is formed inside the variable resistance element film by voltage and electric current applied externally, which causes a shift to the “ON” state, and as the conductive path formed inside the variable resistance element film is lost, which causes a shift to the “OFF” state. ReRAM cells have a configuration including two electrodes with the variable resistance element film therebetween. By using the electric-field inductive colossal electro-resistance change effects (Colosal Electro-Resistance), for example, by applying an electric field, filament is produced inside the variable resistance element film composed of a metal oxide or a conductive path is formed between the two electrodes to cause a shift to the “ON” state. Subsequently, the filament is lost by applying an inverse electric field or the conductive path formed between the two electrodes is lost to cause a shift to the “OFF” state. By inverting the direction of the electric field applied, the switching is achieved between the “ON” state and the “OFF” state, in which the resistance value between the two electrodes varies largely. Data is stored by using the fact that the electric current flowing through the storage element varies depending on the resistance value between the “ON” state and the “OFF” state. To write data, in accordance with data to be stored, the voltage value, the current value, and pulse width are determined for causing a transition from the “OFF” state to the “ON” state and a transition from the “ON” state to the “OFF” state, whereby the filament for data storage is produced or lost or the conductive path is formed or lost.

NPL 1 discloses a non-volatile switching element as a type of variable resistance non-volatile switching element applicable to the configuration of the ReRAM. As a variable resistance element that is likely to increase the flexibility of “circuit” layout used for the configuration of ReRAM memory cells, the non-volatile switching element performs switching by reversibly changing the resistance value between the electrodes with the variable resistance element film interposed therebetween, by using movement of metal ions in the ion conductors, “precipitation of metal by reduction of metal ions” as a result of an electrochemical reaction, and “generation of metal ions by oxidation of metal”. The non-volatile switching element disclosed in NPL 1 includes an “ion conducting layer” composed of an ion conductor, and a “first electrode” and a “second electrode” provided to be in contact with two respective surfaces of the “ion conducting layer”. A “first metal” forming the “first electrode” and a “second metal” forming the “second electrode” included in the non-volatile switching element have different values of standard Gibbs energy AG of formation in the process of oxidizing metal and generating metal ions.

In the non-volatile switching element disclosed in NPL 1, the “first metal” forming the “first electrode” and the “second metal” forming the “second electrode” are selected as follows.

A “bias voltage” is applied between the “first electrode” and the “second electrode” to cause a transition from the “OFF” state to the “ON” state. Selected as the “first metal” forming the “first electrode” is such a metal that can be oxidized to generate metal ions by an electrochemical reaction induced by the applied “bias voltage” in the boundary between the “first electrode” and the “ion conducting layer”, whereby the metal ions can be supplied to the “ion conducting layer”.

A “bias voltage” is applied between the “first electrode” and the “second electrode” to cause a transition from the “ON” state to the “OFF” state. When the “first metal” precipitates on the surface of the “second electrode”, the “first metal” precipitating on the surface of the “second electrode” is oxidized to generate metal ions by an electrochemical reaction induced by the applied “bias voltage” and the metal ions dissolved in the “ion conducting layer”. Selected as the “second metal” forming the “second electrode” is such a metal that can be oxidized by the applied “bias voltage” but no process to generate metal ions is induced in this reaction.

The following briefly describes the switching operation of a metal cross-linked variable resistance element that can achieve the “ON” state and the “OFF” state by the “formation of a metal cross-linked structure” and “dissolution of the metal cross-linked structure”.

In a transition process (set process) from the “OFF” state to the “ON” state, the second electrode is grounded and a positive voltage is applied to the first electrode. As a result, in the boundary of the first electrode and the conducting layer, the metal forming the first electrode is ionized and the resultant metal ions dissolved in the ion conducting layer. On the second electrode side, electrons supplied by the second electrode cause the metal ions in the ion conducting layer to precipitate in the form of metal in the ion conducting layer. The metal precipitating in the ion conducting layer forms a metal cross-linked structure. Eventually, the metal cross-link connecting the first electrode and the second electrode is formed. By electrically connecting the first electrode and the second electrode through the metal cross-link, the switch is turned into the “ON” state.

By contrast, in a transition process (reset process) from the “ON” state to the “OFF” state, the second electrode is grounded relative to the “ON” state and a negative voltage is applied to the first electrode. As a result, the metal forming the metal cross-link is ionized and the resultant metal ions dissolved in the ion conducting layer. As dissolution advances, a part of the “metal cross-linked structure” forming the metal cross-link is disconnected. Eventually, when the metal cross-link connecting the first electrode and the second electrode is disconnected, their electrical connection is also terminated and the switch is turned into the “OFF” state.

As the dissolution of the metal advances, the “metal cross-linked structure” forming a conductive path becomes narrower, the resistance increases between the first electrode and the second electrode, dissolving metal ions are reduced and precipitate in the form of metal in the boundary of the first electrode and the ion conducting layer, and therefore the metal ion concentration in the “ion conducting layer” decreases and the relative dielectric constant changes. Accordingly, the electric properties are changed from the preceding stage where the electric connection remains, for example, the capacitance between the electrodes changes, and the electric connection is terminated eventually.

When the second electrode is grounded and a positive voltage is applied to the “OFF” state first electrode again in the metal cross-linked variable resistance element having been transited to the “OFF” state (reset), a transition process (set process) from the “OFF” state to the “ON” state advances. In other words, in the metal cross-linked variable resistance element, the transition process (set process) from the “OFF” state to the “ON” state and the transition process (reset process) from the “ON” state to the “OFF” state can be performed reversibly.

NPL 1 discloses the configuration of a two-terminal switching element in which two electrodes are provided with an ion conductor therebetween and the conductive state between the two electrodes is controlled and also discloses the switching operation of the switching element.

Two-terminal switching elements to which the above-described variable resistance elements are applied are characterized in that they are smaller than semiconductor switches such as MOSFETs and they have smaller resistances in the “ON” state. Because of these characteristics, the two-terminal switching elements are considered to be suitably applied to programmable logic devices. In addition, the conductive state (the “ON” state or the [OFF] state) can be maintained in the variable resistance switching elements without application of voltages used for the set operation and the reset operation after the set operation and the reset operation. Variable resistance switching elements are therefore applicable to switching elements forming non-volatile memory elements.

To form a non-volatile memory element, a selection element, such as a transistor, and a switching element form a memory cell as a basic unit. A plurality of such memory cells are arrayed in the longitudinal direction and the lateral direction to form a “cell matrix”. By arraying the memory cells in a matrix, a specific memory cell in the memory cells in a matrix can be selected by selecting a corresponding word line and bit line. The conductive state (the “ON” state or the [OFF] state) of the switching element of the selected memory cell is sensed. Based on the “ON” state or the [OFF] state of the switching element, which information “1” or “0” the switching element stores can be read. In this manner, a non-volatile memory is achieved.

NPL 1 discloses a switching element (solid electrolyte switch) that uses “formation of metal cross-link” and “dissolution of metal cross-link” because of movement of metal ions in an ion conductor (a solid electrolyte in which ions can move in accordance with an electric field applied) and an electrochemical reaction, that is, generation of metal ions through oxidation of metal (oxidation reaction) and precipitation of metal through reduction of metal ions (reduction reaction). The switching element disclosed in NPL 1 includes an ion conducting layer, and a first electrode (active electrode) and an opposing second electrode (inactive electrode) with the ion conducting layer interposed therebetween. The first electrode plays a role of supplying metal ions to the ion conducting layer during the process of “formation of metal cross-link”. In the process of “dissolution of metal cross-link”, no metal ions are generated (oxidation reaction) through oxidation of the metal forming the second electrode, whereas generation of metal ions through oxidation of the metal forming the metal cross-link advances.

### Citation List

### Non Patent Literature

[NPL 1] M. Tada, K. Okamoto, T. Sakamoto, M. Miyamura, N. Banno, and H. Hada, “Polymer Solid-Electrolyte (PSE) Switch Embedded on CMOS for Nonvolatile Crossbar Switch”, IEEE TRANSACTION ON ELECTRON DEVICES, Vol. 58, No. 12, pp. 4398-4405, (2011).

### SUMMARY OF INVENTION

### Technical Problem

The variable resistance switching elements used for the above-described MRAM, PRAM, and ReRAM are as follows:

the MRAM is a magnetoresistive element that uses magnetoresistive effects illustrated as an example in FIG. 14;

the PRAM is a phase-change variable resistance element that uses phase-change material (e.g., Ge₂Sb₂Te₅) that can causes a reversible phase change between the “high-resistance amorphous state” and the “low-resistance crystalline state illustrated as an example in FIG. 15; and

the ReRAM is an oxygen-deficient variable resistance element that uses a variable resistance film composed of a metal oxide exhibiting electric-field inductive colossal electro-resistance change effects (Colosal Electro-Resistance) illustrated as an example in FIG. 17 or a metal cross-linked variable resistance element that uses a variable resistance film composed of a solid electrolyte. The “magnetic material” used in the magnetoresistive element; the “phase-change material (e.g., Ge₂Sb₂Te₅)” used in the phase-change variable resistance element; and the “metal oxide” used in the oxygen-deficient variable resistance element and the “metal electrode” that forms, together with the “metal oxide”, metal-“metal oxide” joining; the “solid electrolyte” that is used as the “ion conducting layer”, the “first electrode” that is used as the “ion supplying layer”, and the “second electrode” that injects electrons into the “ion conducting layer” in the metal cross-linked variable resistance element may, for example, lose their properties when “oxidized” and the target properties of the variable resistance elements can fail to be achieved. In addition, when a “porous film” used as the “ion conducting layer” in the metal cross-linked variable resistance element absorbs moisture (water), the absorbed water can cause “leak current” in the “OFF” state.

The variable resistance switching elements are provided in wiring layers above semiconductor substrates, and the variable resistance switching elements are provided in interlayer insulation films. To prevent “oxidation” and “absorption of moisture” during the formation of the interlayer insulation films, a configuration is employed for covering the variable resistance switching element with passivation films (protective insulation films) having excellent insulation, oxidation resistant, and moisture resistant properties. In the metal cross-linked variable resistance element described in NPL 1, for example, the periphery of the metal cross-linked variable resistance element is covered with a SiN film having excellent insulation, oxidation resistant, and moisture resistant properties, whereby oxidation resistance and moisture resistance are improved. The formation of passivation films (protective insulation films) should not involve the potential to cause “oxidation” or “absorption of moisture”. In addition, to cover side wall surfaces of the variable resistance switching elements, the passivation films need to be formed using an isotropic deposition method that can offer an excellent step coverage. In this sense, SiN films and SiCN films, which are deposited by plasma-enhanced CVD, which is an isotropic deposition method, and require no material containing oxygen are suitable insulation materials as passivation films (protective insulation films).

The excellent passivation properties of SiN films and SiCN films, which are deposited by plasma-enhanced CVD, such as the effects of improving oxidation resistance and moisture resistance, are caused by the fact that high densities of the SiN films and SiCN films formed can prevent oxygen or water from passing through the SiN films and SiCN films. By using their low film permeability, the highly dense SiN films and SiCN films are used as insulating barrier films for preventing diffusion of copper.

As compared with SiO₂ films and SiOC films used interlayer insulation films as in multi-layered copper wiring films, the highly dense SiN films and SiCN films have higher relative-dielectric constants k. In a 65-nm-generation copper multi-layered wiring, for example, a low dielectric film is introduced as an insulating material forming an interlayer insulation film, and the effective relative-dielectric constants k_{eff} of the interlayer insulation film is: k_{eff}=about 3 to 3.5. By contrast, SiN films have a relative dielectric constant of 7.

The inventors of the present invention have found that, when a variable resistance element of a miniaturized semiconductor device is mounted, and when an insulation material used for forming a passivation film has a high relative-dielectric constants, using the passivation film as one of a plurality of insulation films forming the interlayer insulation film can increase the effective relative-dielectric constants k_{eff} of the interlayer insulation film. The inventors of the present invention have also found that this increase in the effective relative-dielectric constants k_{eff} of the interlayer insulation film leads to an increase in the parasitic capacitance of the wires in the copper multi-layered wiring, which may result in a signal delay and increased power consumption. The inventors of the present invention have also found that, in the metal cross-linked variable resistance element described in NPL 1, for example, adopting a SiN film as a passivation film (protective insulation film) involves a problem in that the parasitic capacitance of the wires in the multi-layered wiring layer on which the metal cross-linked variable resistance element is mounted can increase.

The present invention aims to solve the problem found through the research made by the inventors. In other words, it is an object of the present invention to provide a variable resistance element that has a novel configuration, a semiconductor device using the variable resistance element, and a method for producing the resistance element. The variable resistance element is provided in a multi-layered wiring layer and is covered by a passivation film (protective insulation film) for improving oxidation resistance and moisture resistance. When a SiN film is adopted as the passivation film, a highly reliable variable resistance element can be achieved while the parasitic capacitance of the wires in the multi-layered wiring layer on which the variable resistance element is mounted can be kept low.

### Solution to Problem

The inventors of the present invention have found that, to solve the above-described problem, when a SiN film is adopted as a passivation film (protective insulation film) for improving oxidation resistance and moisture resistance to cover the variable resistance element, it is effective that a part of the passivation film (protective insulation film) not used for covering the variable resistance element be removed. Using this configuration can prevent the passivation film from being used as one of a plurality of insulation films forming an interlayer insulation film.

In this process, another part of the passivation film that is used for covering the variable resistance element remains unremoved. By forming the interlayer insulation film so as to cover the remaining passivation film (protective insulation film), a desired variable resistance element can be provided in a wiring layer on a semiconductor substrate.

The inventors have completed the present invention based on the above-described knowledge to overcome the problem that they have identified, thereby solving the problem.

Specifically, a variable resistance element according to the present invention is

a variable resistance element provided in a wiring layer on a semiconductor substrate,

the wiring layer including a first interlayer insulation film and a second interlayer insulation film positioned above the first interlayer insulation film,

the variable resistance element including:
a variable resistance film formed on the first interlayer insulation film; and
a first electrode formed in contact with an upper surface of the variable resistance film,

a side surface of the variable resistance element including the variable resistance film and the first electrode being provided with a protective insulation film that covers at least a side surface of the variable resistance film,

at least the protective insulation film provided to the side surface of the variable resistance element being covered with a second interlayer insulation film,

the second interlayer insulation film and the first interlayer insulation film being directly in contact with each other.

When the protective insulation film is formed of a SiN film, the effects of the present invention are more prominent.

Preferably, a wiring forming the wiring layer is a copper wiring, and

the first interlayer insulation film is in contact with an upper surface of a copper wiring in a lower layer.

Preferably in this configuration,

the first interlayer insulation film has an opening, and

the variable resistance film in the variable resistance element is in contact with the upper surface of the copper wiring in the lower layer through the opening.

Preferably, the first interlayer insulation film is formed of a SiN film or a SiCN film.

The first electrode may be formed of a metal containing Ru as a main component, and

the variable resistance film may be a film formed of a solid electrolyte.

Preferably, the film formed of the solid electrolyte is a porous film.

In the variable resistance element according to the present invention,

the variable resistance film may contain an oxide.

Preferably, the second interlayer insulation film is a SiO₂ film.

More preferably, an upper surface of the first electrode is provided with an upper surface protection film, and

the protective insulation film covers side surfaces of the variable resistance film, the first electrode, and the upper surface protection film.

### Advantageous Effects of Invention

By adopting the configuration of any of the variable resistance elements according to the present invention, the parasitic capacitance between upper and lower wiring layers forming the multi-layered wiring layer can be kept low while high reliability of the variable resistance element provided in the wiring layer on the semiconductor substrate is maintained.

### BRIEF DESCRIPTION OF THE DRAWINGS

FIG. 1 is a cross-sectional view schematically illustrating one configuration example of a variable resistance element according to a first exemplary embodiment of the present invention, used as a non-volatile switching element provided in a multi-layered wiring layer in a semiconductor device.

FIG. 2 is a cross-sectional view schematically illustrating one configuration example of a variable resistance element according to a second exemplary embodiment of the present invention, used as a non-volatile switching element provided in a multi-layered wiring layer in a semiconductor device.

FIG. 3 is a cross-sectional view schematically illustrating one configuration example of a variable resistance element according to a third exemplary embodiment of the present invention, used as a non-volatile switching element provided in a multi-layered wiring layer in a semiconductor device.

FIG. 4 is a cross-sectional view schematically illustrating one configuration example of a variable resistance element according to a fourth exemplary embodiment of the present invention, used as a non-volatile switching element provided in a multi-layered wiring layer in a semiconductor device.

FIG. 5 is a cross-sectional view schematically illustrating one configuration example of a variable resistance element according to a fifth exemplary embodiment of the present invention, used as a non-volatile switching element provided in a multi-layered wiring layer in a semiconductor device.

FIG. 6 is a cross-sectional view schematically illustrating one configuration example of a variable resistance element according to a sixth exemplary embodiment of the present invention, used as a non-volatile switching element provided in a multi-layered wiring layer in a semiconductor device.

FIG. 7 is a cross-sectional view schematically illustrating a first mode of the variable resistance element according to the third exemplary embodiment of the present invention, used as the non-volatile switching element provided in the multi-layered wiring layer of the semiconductor device.

FIG. 8 is a cross-sectional view schematically illustrating a second mode of the variable resistance element according to the third exemplary embodiment of the present invention, used as the non-volatile switching element provided in the multi-layered wiring layer of the semiconductor device.

FIG. 9 is a cross-sectional view schematically illustrating a third mode of the variable resistance element according to the third exemplary embodiment of the present invention, used as the non-volatile switching element provided in the multi-layered wiring layer of the semiconductor device.

FIG. 10 is a cross-sectional view schematically illustrating a mode in which a protective insulation film is interposed between a first interlayer insulation film and a second interlayer insulation film, in place of another mode in which the first interlayer insulation film and the second interlayer insulation film are in direct contact with each other, which is adopted in the “third mode” illustrated in FIG. 9.

FIG. 11 is a cross-sectional view schematically illustrating a fourth mode of the variable resistance element according to the third exemplary embodiment of the present invention, used as the non-volatile switching element provided in the multi-layered wiring layer of the semiconductor device.

FIG. 12A is a cross-sectional view illustrating an example process for producing the variable resistance element according to the third exemplary embodiment of the present invention, used as the non-volatile switching element provided in the multi-layered wiring layer of the semiconductor device, schematically illustrating step B1 in a series of processing of a process for producing the variable resistance element according to a fifth mode.

FIG. 12B is a cross-sectional view illustrating the example process for producing the variable resistance element according to the third exemplary embodiment of the present invention, used as the non-volatile switching element provided in the multi-layered wiring layer of the semiconductor device, schematically illustrating step B2 in a series of processing of the process for producing the variable resistance element according to the fifth mode.

FIG. 12C is a cross-sectional view illustrating the example process for producing the variable resistance element according to the third exemplary embodiment of the present invention, used as the non-volatile switching element provided in the multi-layered wiring layer of the semiconductor device, schematically illustrating step B3 in a series of processing of the process for producing the variable resistance element according to the fifth mode.

FIG. 12D is a cross-sectional view illustrating the example process for producing the variable resistance element according to the third exemplary embodiment of the present invention, used as the non-volatile switching element provided in the multi-layered wiring layer of the semiconductor device, schematically illustrating step B4 in a series of processing of the process for producing the variable resistance element according to the fifth mode.

FIG. 12E is a cross-sectional view illustrating the example process for producing the variable resistance element according to the third exemplary embodiment of the present invention, used as the non-volatile switching element provided in the multi-layered wiring layer of the semiconductor device, schematically illustrating step B5 in a series of processing of the process for producing the variable resistance element according to the fifth mode.

FIG. 12F is a cross-sectional view illustrating the example process for producing the variable resistance element according to the third exemplary embodiment of the present invention, used as the non-volatile switching element provided in the multi-layered wiring layer of the semiconductor device, schematically illustrating step B6 in a series of processing of the process for producing the variable resistance element according to the fifth mode.

FIG. 12G is a cross-sectional view illustrating the example process for producing the variable resistance element according to the third exemplary embodiment of the present invention, used as the non-volatile switching element provided in the multi-layered wiring layer of the semiconductor device, schematically illustrating step B7 in a series of processing of the process for producing the variable resistance element according to the fifth mode.

FIG. 12H is a cross-sectional view illustrating the example process for producing the variable resistance element according to the third exemplary embodiment of the present invention, used as the non-volatile switching element provided in the multi-layered wiring layer of the semiconductor device, schematically illustrating step B8 in a series of processing of the process for producing the variable resistance element according to the fifth mode.

FIG. 12I is a cross-sectional view illustrating the example process for producing the variable resistance element according to the third exemplary embodiment of the present invention, used as the non-volatile switching element provided in the multi-layered wiring layer of the semiconductor device, schematically illustrating step B9 in a series of processing of the process for producing the variable resistance element according to the fifth mode.

FIG. 13 is a diagram illustrating a switching process of a copper filament variable resistance element, the upper side illustrating a transition process (set process) from an “OFF” state to an “ON” state and the lower side illustrating a transition process (reset process) from the “ON” state to the “OFF” state.

FIG. 14 is a schematic view schematically illustrating one configuration example of an MRAM (Magnetic RAM).

FIG. 15 is a schematic view schematically illustrating one configuration example of a PRAM (Phase-change RAM).

FIG. 16 is a schematic view schematically illustrating one configuration example of an FRAM (Ferroelectric RAM).

FIG. 17 is a schematic view schematically illustrating one configuration example of a ReRAM (Resistive RAM).

### DESCRIPTION OF EMBODIMENTS

The following describes the present invention in greater detail.

### First Exemplary Embodiment

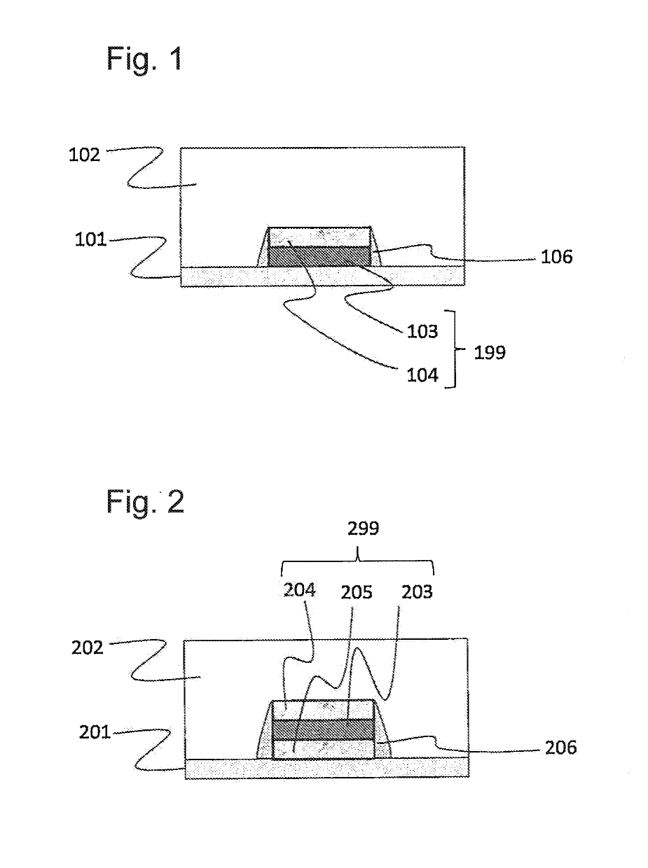

A semiconductor device in which a variable resistance element according to a first exemplary embodiment of the present invention is used as a non-volatile switching element provided in a multi-layered wiring layer is described with reference to the drawings. FIG. 1 is a cross-sectional view schematically illustrating one configuration example of the variable resistance element according to the first exemplary embodiment of the present invention, used as the non-volatile switching element provided in the multi-layered wiring layer of the semiconductor device.

As illustrated in FIG. 1, a variable resistance element 199 according to the first exemplary embodiment is formed in a wiring layer on a semiconductor substrate (not illustrated). A multi-layered wiring layer, in which the variable resistance element 199 is formed, includes a first interlayer insulation film 101 and a second interlayer insulation film 102 positioned above the first interlayer insulation film 101. The variable resistance element 199 is formed above the first interlayer insulation film 101, and includes a first electrode 104 and a variable resistance film 103. The variable resistance element 199 has side surfaces of the first electrode 104 and the variable resistance film 103 covered with a protective insulation film 106. The second interlayer insulation film 102 positioned above the first interlayer insulation film 101 is in direct contact with the first interlayer insulation film 101.

The variable resistance film 103 is in contact with a surface of a wiring layer in a lower layer (not illustrated) via a hole (positioned a closer or farther side in front view and thus is not illustrated) opened in the first interlayer insulation film 101. Thus, in a portion of the opened hole, the variable resistance film 103 has lower and upper surfaces respectively in contact with the wiring layer in the lower layer and the first electrode 104.

When the variable resistance film 103 is formed of a solid electrolyte and the wiring layer in the lower layer is a copper layer, the wiring layer in the lower layer serves as an ion supplying layer that generates copper ions through an electrochemical reaction and supplies the copper ions to the variable resistance film 103. Thus, a copper filament precipitating variable resistance element is obtained in which the variable resistance film 103 serves as the “ion conducting layer”, the wiring layer in the lower layer serves as the “first electrode” functioning as “the ion supplying layer”, and the first electrode 104 serves as the “second electrode”.

In the variable resistance element 119 according to the first exemplary embodiment as the copper filament precipitating variable resistance element, the variable resistance film 103 is a film formed of a solid electrolyte and functioning as the ion conductor in which copper ions can move. As the solid electrolyte forming the variable resistance film 103, TaO, TaSiO, SiO₂, ZrO₂, HfO₂, TiO₂, Al₂O₃, an organic polymer film, an organic polymer film including SiO, or the like may be used. The first electrode 104 is an electrode including metal with a smaller absolute value of standard Gibbs energy ΔG of formation in oxidation (process of generating metal ions from the metal) than that of copper. As the metal with a smaller absolute value of standard Gibbs energy AG of formation in oxidation (process of generating metal ions from the metal) than that of copper, Ru or Pt may be used, for example. The first electrode 104 may form a stacked structure including a lower layer portion that contacts the variable resistance film 103 and an upper layer portion stacked on the lower layer portion. In the structure, the lower layer portion is formed of metal with a smaller absolute value of standard Gibbs energy AG of formation in oxidation (process of generating metal ions from the metal) than that of copper. For example, the first electrode 104 may employ a stacked structure of Ru (lower layer)/Ta (upper layer).

When the variable resistance element 199 is the copper filament precipitating variable resistance element having the stacked structure including the wiring layer in the lower layer, the variable resistance film 103, and the first electrode 104 formed in the hole portion opened in the first interlayer insulation film 101, the first interlayer insulation film 101 covers the upper surface of the wiring layer in the lower layer. The first interlayer insulation film 101 may be formed of a SiN film, a SiCN film, a SiC film, or a stacked film of these or other insulation films. The second interlayer insulation film 102 may be formed of a SiO₂ film or a SiOC film. The second interlayer insulation film 102 is formed to cover the upper surfaces of the variable resistance element 199 and the first interlayer insulation film 101, and thus is in direct contact with the first interlayer insulation film 101.

The variable resistance element 199 has the sides surfaces of the first electrode 104 and the variable resistance film 103 covered with the protective insulation film 106. The protective insulation film 106 may be formed by using a SiN film. By forming the protective insulation film 106, metal oxides can be prevented from being generated on the lower surface of the first electrode 104, in contact with the variable resistance film 103, due to the oxidation developed from the side surface of the first electrode 104, when the second interlayer insulation film 102 is formed.

Water entering the solid electrolyte from the side surface of the variable resistance film 103 causes “leak current” when the variable resistance element 199 is in the “high-resistive state”.

The water (H₂O) entering the solid electrolyte from the side surface of the variable resistance film 103 causes oxidation of the copper filament formed in the variable resistance film 103, oxidation of the upper surface of the wiring layer in the lower layer (copper wiring layer) in contact with the variable resistance film 103, or oxidation of the lower surface of the first electrode 104 in contact with the variable resistance film 103. Thus, the oxidation caused by the entering water (H₂O) is a cause of a failure of changing the resistive state of the variable resistance element 199. By forming the protective insulation film 106, the entrance of water into the solid electrolyte from the side surface of the variable resistance film 103 can be prevented, whereby the occurrence of the failure can be prevented.

When the variable resistance element 199 is the copper filament precipitating variable resistance element having the stacked structure including the wiring layer in the lower layer, the variable resistance film 103, and the first electrode 104 formed in the hole portion opened in the first interlayer insulation film 101, programing (switching) can be performed by applying a predetermined programming voltage between the wiring layer in the lower layer and the first electrode 104.

### Second Exemplary Embodiment

A semiconductor device in which a variable resistance element according to a second exemplary embodiment of the present invention is used as a non-volatile switching element provided in a multi-layered wiring layer is described with reference to the drawings. FIG. 2 is a cross-sectional view schematically illustrating one configuration example of the variable resistance element according to the second exemplary embodiment of the present invention, used as the non-volatile switching element provided in the multi-layered wiring layer of the semiconductor device.

As illustrated in FIG. 2, a variable resistance element 299 according to the second exemplary embodiment is formed in a wiring layer on a semiconductor substrate (not illustrated). A multi-layered wiring layer, in which the variable resistance element 299 is formed, includes a first interlayer insulation film 201 and a second interlayer insulation film 202 positioned above the first interlayer insulation film 201. The variable resistance element 299 is formed on the first interlayer insulation film 201, and includes a first electrode 204, a variable resistance film 203, and a second electrode 205. The variable resistance element 299 has side surfaces of the first electrode 204, the variable resistance film 203, and the second electrode 205 covered with a protective insulation film 206. The second interlayer insulation film 202 positioned above the first interlayer insulation film 201 is in direct contact with the first interlayer insulation film 201.

When the variable resistance element 299 according to the second exemplary embodiment is an oxygen-deficit variable resistance element, the variable resistance film 203 is formed of an oxide that functions as a solid electrolyte. The variable resistance film 203 may be formed of TaO, TaSiO, ZrO₂, HfO₂, TiO₂, SiO₂, Al₂O₃, a stacked structure of these, or the like. The first electrode 204, in contact with the upper surface of the variable resistance film 203, and the second electrode 205, in contract with the lower surface of the variable resistance film 203, may be formed by using Pt, Ru, Ir, Ti, Ta, Hf, Zr, Al, W, or a nitrogen compound composed of the same.

The side surfaces of the first electrode 204, the variable resistance film 203, and the second electrode 205 that form the variable resistance element 299 are covered with the protective insulation film 206.

When the variable resistance element 299 according to the second exemplary embodiment is the oxygen-deficit variable resistance element, the first interlayer insulation film 201 in contact with the second electrode 205 may be formed of a SiN film, a SiCN film, a SiC film, or a stacked film of these or other insulation films. The second interlayer insulation film 202, which covers the upper surface of the first electrode 204, is formed of a SiO₂ film or a SiOC film.

By forming the protective insulation film 206 by using the SiN film, metal oxides can be prevented from being generated on the lower surface of the first electrode 204, in contact with the upper surface of the variable resistance film 203, and on the upper surface of the second electrode 205, in contact with the lower surface of the variable resistance film 203, due to the oxidation developed from the side surfaces of the first electrode 204 and the second electrode 205, when the second interlayer insulation film 202 is formed.

Water entering the solid electrolyte from the side surface of the variable resistance film 203 causes “leak current” when the variable resistance element 299 is in the “high-resistive state”.

In case that the side surfaces are not covered with the protective insulation film 206, oxygen desorption may occurs from side surfaces of the oxide film forming the variable resistance film 203 when the second interlayer insulation film 202 is formed, thereby causes transition of an average oxidation number around the side surfaces of the oxide film to be out of the average oxidation number of oxide films. Thus, the oxygen desorption is a cause of a failure of changing the resistive state of the variable resistance element 299. By covering the side surfaces with the protective insulation film 206, the occurrence of the failure can be prevented.

When the variable resistance element 299 is the oxygen deficit resistance element having the stacked structure including the second electrode 205, the variable resistance film 203, and the first electrode 204, programming (switching) can be performed by applying a predetermined programming voltage between the second electrode 205 and the first electrode 204.

### Third Exemplary Embodiment

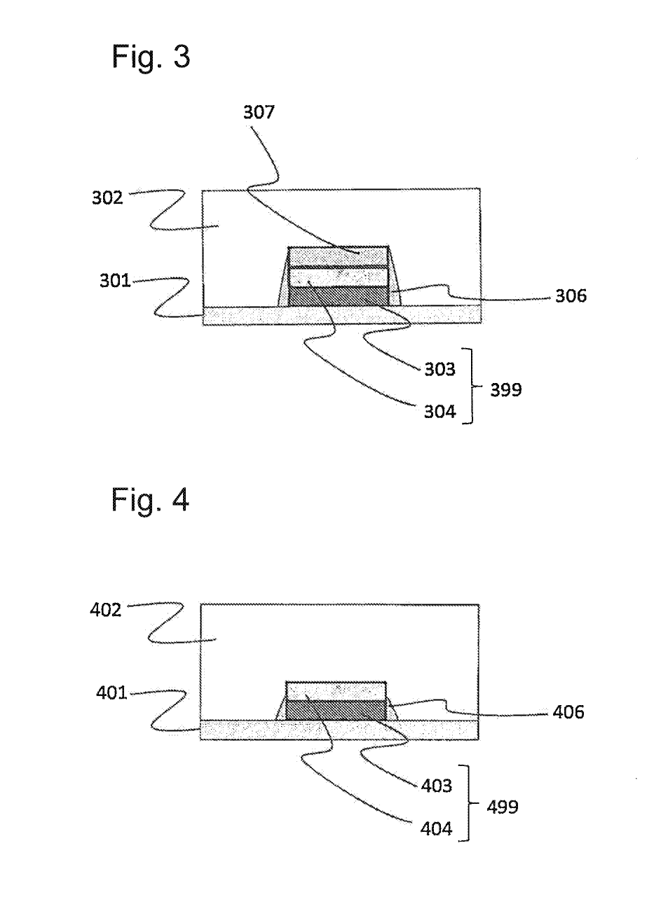

A semiconductor device in which a variable resistance element according to a third exemplary embodiment of the present invention is used as a non-volatile switching element provided in a multi-layered wiring layer is described with reference to the drawings. FIG. 3 is a cross-sectional view schematically illustrating one configuration example of the variable resistance element according to the third exemplary embodiment of the present invention, used as the non-volatile switching element provided in the multi-layered wiring layer of the semiconductor device.

As illustrated in FIG. 3, a variable resistance element 399 according to the third exemplary embodiment is formed in a wiring layer on a semiconductor substrate (not illustrated). A multi-layered wiring layer, in which the variable resistance element 399 is formed, includes a first interlayer insulation film 301 and a second interlayer insulation film 302 positioned above the first interlayer insulation film 301. The variable resistance element 399 is formed on the first interlayer insulation film 301, and includes a first electrode 304 and a variable resistance film 303, and is provided with an upper surface protection film 307 that covers the upper surface of the first electrode 304.

The variable resistance element 399 has at least side surfaces of the first electrode 304 and the variable resistance film 303 covered with a protective insulation film 306. As illustrated in FIG. 3, the protective insulation film 306 also covers the side surface of the upper surface protection film 307. The second interlayer insulation film 302 positioned above the first interlayer insulation film 301 is in direct contact with the first interlayer insulation film 301.

The variable resistance film 303 is in contact with a surface of a wiring layer in a lower layer (not illustrated) via a hole (positioned on a closer or farther side in front view and thus is not illustrated) opened in the first interlayer insulation film 301. Thus, in a portion of the opened hole, the lower surface of the variable resistance film 303 is in contact with a wiring layer in a lower layer and the upper surface of the variable resistance film 303 is in contact with the first electrode 304.

When the variable resistance film 303 is formed of a solid electrolyte and the wiring layer in the lower layer is a copper wiring layer, the wiring layer in the lower layer functions as an ion supplying layer that generates copper ions through an electrochemical reaction and supplies the copper ions to the variable resistance film 303. Thus, a copper filament precipitating variable resistance element is obtained in which the variable resistance film 303 serves as the “ion conducting layer”, the wiring layer in the lower layer serves as the “first electrode” functioning as the “ion supplying layer”, and the first electrode 304 serves as the “second electrode”.

Thus, except for the upper surface protection film 307 and the protective insulation film 306, the configuration of the variable resistance element according to the third exemplary embodiment illustrated in FIG. 3 can be selected to be substantially the same as the configuration of the variable resistance element according to the first exemplary embodiment described above illustrated in FIG. 1.

When the variable resistance element 399 is the copper filament precipitating variable resistance element having the stacked structure including the wiring layer in the lower layer, the variable resistance film 303, and the first electrode 304 formed in the hole portion opened in the first interlayer insulation film 301, the first interlayer insulation film 301 covers the upper surface of the wiring layer in the lower layer. In this structure, the first interlayer insulation film 301 may be formed of a SiN film, a SiCN film, a SiC film, or a stacked film of these or other insulation films. The second interlayer insulation film 302 may be formed of a SiO₂ film or a SiOC film. The second interlayer insulation film 302 is formed to cover the upper surfaces of the variable resistance element 399 and the first interlayer insulation film 301, and thus is in direct contact with the first interlayer insulation film 301.

In the variable resistance element according to the third exemplary embodiment illustrated in FIG. 3, the protective insulation film 306 is preferably formed by using a SiN film, as in the case of the protective insulation film 106 in the variable resistance element according to the first exemplary embodiment illustrated in FIG. 1. By forming the protective insulation film 306, metal oxides can be prevented from being generated on the lower surface of the first electrode 304, in contact with the variable resistance film 303, due to the oxidation developed from the side surface of the first electrode 304, when the second interlayer insulation film 302 is formed.

Water entering the solid electrolyte from the side surface of the variable resistance film 303 causes “leak current” when the variable resistance element 399 is in the “high-resistive state”.

The water (H₂O) entering the solid electrolyte from the side surface of the variable resistance film 303 causes oxidation of the copper filament formed in the variable resistance film 303, oxidation of the upper surface of the wiring layer in the lower layer (copper wiring layer) in contact with the variable resistance film 303, or oxidation of the lower surface of the first electrode 304 in contact with the variable resistance film 303. Thus, the oxidation caused by the entering water (H₂O) is a cause of a failure of changing the resistive state of the variable resistance element 399. By forming the protective insulation film 306, the entrance of water into the solid electrolyte from the side surface of the variable resistance film 303 can be prevented, whereby the occurrence of the failure can be prevented.

Furthermore, the variable resistance element according to the third exemplary embodiment illustrated in FIG. 3 is provided with the upper surface protection film 307 that covers the upper surface of the first electrode 304 and prevents the upper surface of the first electrode 304 from oxidizing when the second interlayer insulation film 302 is formed. The protective insulation film 307 is preferably formed by using a SiN film, as in the case of the protective insulation film 306.

### Fourth Exemplary Embodiment

A semiconductor device in which a variable resistance element according to a fourth exemplary embodiment of the present invention is used as a non-volatile switching element provided in a multi-layered wiring layer is described with reference to the drawings. FIG. 4 is a cross-sectional view schematically illustrating one configuration example of the variable resistance element according to the fourth exemplary embodiment of the present invention, used as the non-volatile switching element provided in the multi-layered wiring layer of the semiconductor device.

As illustrated in FIG. 4, a variable resistance element 499 according to the fourth exemplary embodiment is formed in a wiring layer on a semiconductor substrate (not illustrated). A multi-layered wiring layer, in which the variable resistance element 499 is formed, includes a first interlayer insulation film 401 and a second interlayer insulation film 402 positioned above the first interlayer insulation film 401. The variable resistance element 499 is formed on the first interlayer insulation film 401, and includes a first electrode 404 and a variable resistance film 403.

The variable resistance element 499 has at least a side surface of the variable resistance film 403 covered with a protective insulation film 406. As illustrated in FIG. 4, the protective insulation film 406 further covers a side surface of a lower portion of the first electrode 404 in contact with the upper surface of the variable resistance film 403. The second interlayer insulation film 402 positioned above the first interlayer insulation film 401 is in direct contact with the first interlayer insulation film 401.

The variable resistance film 403 is in contact with a surface of a wiring layer in a lower layer (not illustrated) via a hole (positioned a closer or farther side in front view and thus is not illustrated) opened in the first interlayer insulation film 401. Thus, in a portion of the opened hole, the lower surface of the variable resistance film 403 is in contact with the wiring layer in a lower layer and the upper surface of the variable resistance film 403 is in contact with the first electrode 404.

When the variable resistance film 403 is formed of a solid electrolyte and the wiring layer in the lower layer is a copper layer, the wiring layer in the lower layer serves as an ion supplying layer that generates copper ions through an electrochemical reaction and supplies the copper ions to the variable resistance film 403. Thus, a copper filament precipitating variable resistance element is obtained in which the variable resistance film 403 serves as the “ion conducting layer”, the wiring layer in the lower layer serves as the “first electrode” functioning as “the ion supplying layer”, and the first electrode 404 serves as the “second electrode”.

Thus, except for the first electrode 404 and the protective insulation film 406, the configuration of the variable resistance element according to the fourth exemplary embodiment illustrated in FIG. 4 can be selected to be substantially the same as the configuration of the variable resistance element according to the first exemplary embodiment described above illustrated in FIG. 1.

In the variable resistance element according to the fourth exemplary embodiment, an upper portion of the first electrode 404, at least except for a lower portion of the first electrode 404 in contact with an upper surface of the variable resistance film 403, is formed by conductive material needless to protect against oxidation. For example, when the entire first electrode 404 or the upper portion of the first electrode 404 is formed of highly oxidation-resistant metal such as Pt, the upper portion of the first electrode 404 requires no protection against the oxidation.

In the variable resistance element according to the fourth exemplary embodiment illustrated in FIG. 4, the protective insulation film 406 is preferably formed by using a SiN film, as in the case of the protective insulation film 106 in the variable resistance element according to the first exemplary embodiment illustrated in FIG. 1. By forming the protective insulation film 406, metal oxides can be prevented from being generated on the lower surface of the first electrode 404, in contact with the variable resistance film 403, due to the oxidation developed from the side surface of the lower portion of the first electrode 404, when the second interlayer insulation film 402 is formed.

Water entering the solid electrolyte from the side surface of the variable resistance film 403 causes “leak current” when the variable resistance element 499 is in the “high-resistive state”.

The water (H₂O) entering the solid electrolyte from the side surface of the variable resistance film 403 causes oxidation of the copper filament formed in the variable resistance film 403, oxidation of the upper surface of the wiring layer in the lower layer (copper wiring layer) in contact with the variable resistance film 403, or oxidation of the lower surface of the first electrode 404 in contact with the variable resistance film 403. Thus, the oxidation caused by the entering water (H₂O) is a cause of a failure of changing the resistive state of the variable resistance element 399. By forming the protective insulation film 406, the entrance of water into the solid electrolyte from the side surface of the variable resistance film 403 can be prevented, whereby the occurrence of the failure can be prevented.

### Fifth Exemplary Embodiment

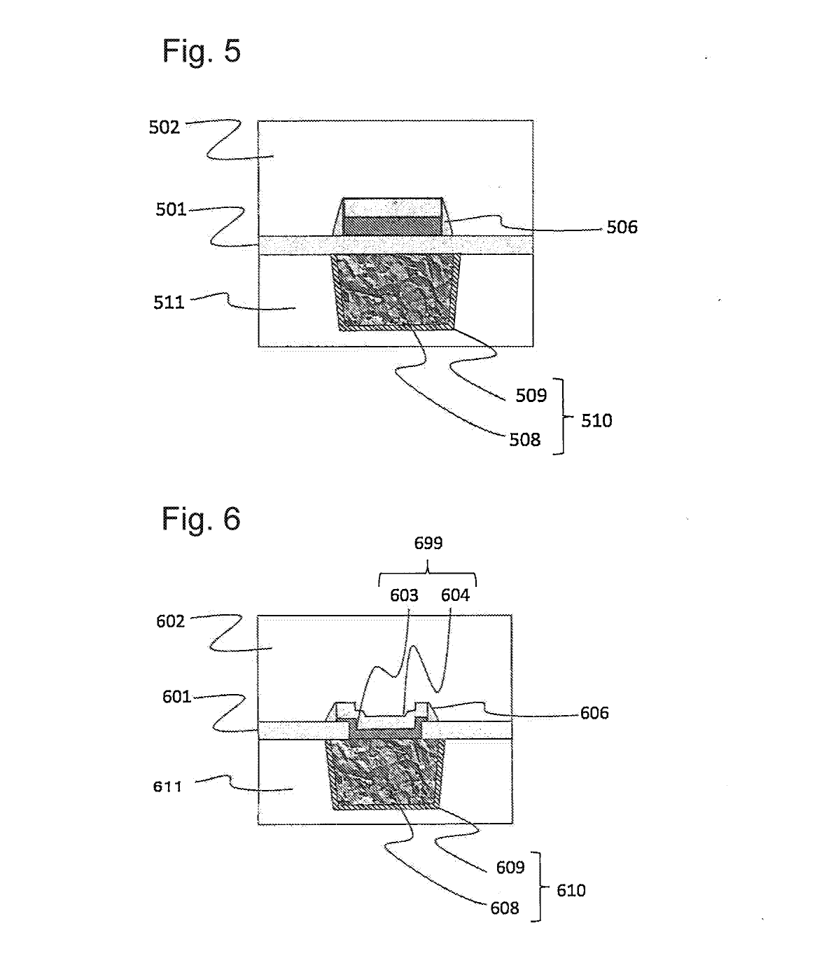

A semiconductor device in which a variable resistance element according to a fifth exemplary embodiment of the present invention is used as a non-volatile switching element provided in a multi-layered wiring layer is described with reference to the drawings. FIG. 5 is a cross-sectional view schematically illustrating one configuration example of the variable resistance element according to the fifth exemplary embodiment of the present invention, used as the non-volatile switching element provided in the multi-layered wiring layer of the semiconductor device.

As illustrated in FIG. 5, a variable resistance element 599 according to the fifth exemplary embodiment is formed in a copper wiring layer on a semiconductor substrate. A multi-layered wiring layer, in which the variable resistance element 599 is formed, includes a first interlayer insulation film 501 and a second interlayer insulation film 502 positioned above the first interlayer insulation film 501. The variable resistance element 599 is formed on the first interlayer insulation film 501, and includes a first electrode 504 and a variable resistance film 503.

In the copper wiring layer 510 formed on the semiconductor substrate, the copper wiring 508, formed of metal mainly composed of copper, is formed in a wiring trench formed in an interlayer insulation film as a lower layer. The copper wiring 508 has side and bottom surfaces, to be in contact with the wiring trench, covered with barrier metal 509. The barrier metal 509 used for manufacturing the copper wiring layer 510 is made of refractory metal such as Ta, Ti, and W, a nitrogen compound of these, or a stacked structure including the metal and the nitrogen compound.

The first interlayer insulation film 501 is formed to cover the upper surface of the copper wiring layer 510, and has a function as an insulating barrier film for preventing diffusion of copper from the copper wiring layer 510. The first interlayer insulation film 501 is formed of a SiN film, a SiCN film, a SiC film, and the like, or a stacked structure of these, to have the function as the insulating barrier film.

The first interlayer insulation film 501 has the function as an insulating barrier film for preventing diffusion of copper from the copper wiring layer 510, and thus the second interlayer insulation film 502, positioned above the first interlayer insulation film 501, may be formed of a SiO₂ film or a SiOC film.

The variable resistance element 599 according to the fifth exemplary embodiment is formed on the first interlayer insulation film 501 and includes the first electrode 504 and the variable resistance film 503, as in the case of the variable resistance element 199 according to the first exemplary embodiment.

When the variable resistance element 599 according to the fifth exemplary embodiment forms a copper filament precipitating variable resistance element having the stacked structure, the variable resistance film 503 is in contact with a surface of the copper wiring layer 510 via a hole (positioned a closer or farther side in front view and thus is not illustrated) opened in the first interlayer insulation film 501. Thus, in a portion of the opened hole, the lower surface of the variable resistance film 503 is in contact with the copper wiring layer 510 and the upper surface of the variable resistance film 503 is in contact with the first electrode 504. The copper wiring layer 510 in the lower layer serves as an ion supplying layer that generates copper ions through an electrochemical reaction and supplies the copper ions into the variable resistance film 503. Thus, a copper filament precipitating variable resistance element is obtained in which the variable resistance film 503 serves as the “ion conducting layer”, the copper wiring layer 510 serves as the “first electrode” functioning as “the ion supplying layer”, and the first electrode 504 serves as the “second electrode”.

The variable resistance element 599 has the sides surfaces of the first electrode 504 and the variable resistance film 503 covered with the protective insulation film 506. The protective insulation film 506 may be formed by using a SiN film. By forming the protective insulation film 506, metal oxides can be prevented from being generated on the lower surface of the first electrode 504, in contact with the variable resistance film 503, due to the oxidation developed from the side surface of the first electrode 504, when the second interlayer insulation film 502 is formed.

Water entering the solid electrolyte from the side surface of the variable resistance film 503 causes “leak current” when the variable resistance element 599 is in the “high-resistive state”.

The water (H₂O) entering the solid electrolyte from the side surface of the variable resistance film 503 causes oxidation of the copper filament formed in the variable resistance film 503, oxidation of the upper surface of the wiring layer in the lower layer (copper wiring layer) in contact with the variable resistance film 503, or oxidation of the lower surface of the first electrode 504 in contact with the variable resistance film 503. Thus, the oxidation caused by the entering water (H₂O) is a cause of a failure of changing the resistive state of the variable resistance element 599. By forming the protective insulation film 506, the entrance of water into the solid electrolyte from the side surface of the variable resistance film 503 can be prevented, whereby the occurrence of the failure can be prevented.

A structure is achieved, whereas the first interlayer insulation film 501 is formed of a SiN film with a large relative-dielectric constant, where the second interlayer insulation film 502 is formed of a SiO₂ film or a SiOC film with a small relative-dielectric constant, and where the first interlayer insulation film 501 and the second interlayer insulation film 502 are in direct contact with each other. Thus, a parasitic capacitance between the copper wiring layers in the upper and lower layers, separated from each other by the stacked structure of the first interlayer insulation film 501 and the second interlayer insulation film 502, can be kept low.

### Sixth Exemplary Embodiment

A semiconductor device in which a variable resistance element according to a sixth exemplary embodiment of the present invention is used as a non-volatile switching element provided in a multi-layered wiring layer is described with reference to the drawings. FIG. 6 is a cross-sectional view schematically illustrating one configuration example of the variable resistance element according to the sixth exemplary embodiment of the present invention, used as the non-volatile switching element provided in the multi-layered wiring layer of the semiconductor device.

As illustrated in FIG. 6, a variable resistance element 699 according to the sixth exemplary embodiment is formed in a copper wiring layer on a semiconductor substrate. A multi-layered wiring layer, in which the variable resistance element 699 is formed, includes a first interlayer insulation film 601 and a second interlayer insulation film 602 positioned above the first interlayer insulation film 601.

The variable resistance element 699 according to the sixth exemplary embodiment forms a copper filament precipitating variable resistance element. A variable resistance film 603 is in contact with a surface of the copper wiring layer 610 via a hole opened in the first interlayer insulation film 601. Thus, in a portion of the opened hole, the lower surface of the variable resistance film 603 is in contact with the copper wiring layer 610 and the upper surface of the variable resistance film 603 is in contact with the first electrode 604. A copper wiring 608 of the copper wiring layer 610 in the lower layer serves as an “ion supplying layer” that generates copper ions through an electrochemical reaction and supplies the copper ions into the variable resistance film 603. Thus, a copper filament precipitating variable resistance element is obtained in which the variable resistance film 603 serves as the “ion conducting layer”, the copper wiring 608 of the copper wiring layer 610 serves as the “first electrode” functioning as “the ion supplying layer”, and the first electrode 604 serves as the “second electrode”.

In the copper wiring layer 610 formed on the semiconductor substrate, the copper wiring 608, formed of metal mainly composed of copper, is formed in a wiring trench formed in an interlayer insulation film in a lower layer. The copper wiring 608 has side and bottom surfaces, to be in contact with the wiring trench, covered with barrier metal 609. The barrier metal 609 used for manufacturing the copper wiring layer 610 is made of refractory metal such as Ta, Ti, and W, a nitrogen compound of these, or a stacked structure including the metal and the nitrogen compound. The copper wiring 608 of the copper wiring layer 610 in the lower layer functions as the “ion supplying layer” for supplying copper ions. The “copper” forming the copper wiring 608 may include metal such as Al, Ti, tin (Sn), and Mg as an impurity.

The variable resistance film 603 is formed of a solid electrolyte capable of conducting copper ions and is used as the “ion conducting layer”. As the solid electrolyte capable of conducting copper ions, TaO, TaSiO, SiO₂, ZrO₂, HfO₂, TiO₂, Al₂O₃, an organic polymer film, an organic polymer film including SiO, or the like may be used.

The first interlayer insulation film 601 is formed to cover the upper surface of the copper wiring layer 610, and has a function as an insulating barrier film for preventing diffusion of copper from the copper wiring layer 610. The first interlayer insulation film 601 is formed of a SiN film, a SiCN film, a SiC film, and the like, or a stacked structure of these, to have the function as the insulating barrier film.

In the variable resistance element 699 according to the sixth exemplary embodiment, the lower surface of the variable resistance film 603 is in contact with the surface of the copper wiring 608 of the copper wiring layer 610 in the lower layer through a hole opened in the first interlayer insulation film 601. In the configuration, the upper surface of the variable resistance film 603 is in contact with the first electrode 604. A metal material forming the first electrode 604 is preferably Ru or platinum (Pt).

The variable resistance element 699 has the sides surfaces of the first electrode 604 and the variable resistance film 603 covered with the protective insulation film 606. A side surface of a portion of the variable resistance film 603 formed in the hole opened in the first interlayer insulation film 601 is in contact with a side wall surface of the hole.

The first interlayer insulation film 601 has the function as an insulating barrier film for preventing diffusion of copper from the copper wiring 608 of the copper wiring layer 610, and thus the second interlayer insulation film 602, positioned above the first interlayer insulation film 601, may be formed of a SiO₂ film or a SiOC film.

The protective insulation film 606, covering the side surfaces of the first electrode 604 and the variable resistance film 603, may be formed by using a SiN film. By forming the protective insulation film 606, metal oxides can be prevented from being generated on the lower surface of the first electrode 604, in contact with the variable resistance film 603, due to the oxidation developed from the side surface of the first electrode 604, when the second interlayer insulation film 602 is formed.

Water entering the solid electrolyte from the side surface of the variable resistance film 603 causes “leak current” when the variable resistance element 699 is in the “high-resistive state”.

The water (H₂O) entering the solid electrolyte from the side surface of the variable resistance film 603 causes oxidation of the copper filament formed in the variable resistance film 603, oxidation of the upper surface of the copper wiring 608 of the copper wiring layer 610 in the lower layer in contact with the variable resistance film 603, or oxidation of the lower surface of the first electrode 604 in contact with the variable resistance film 603. Thus, the oxidation caused by the entering water (H₂O) is a cause of a failure of changing the resistive state of the variable resistance element 699. By forming the protective insulation film 606, the entrance of water into the solid electrolyte from the side surface of the variable resistance film 603 can be prevented, whereby the occurrence of the failure can be prevented.

The variable resistance element 699 according to the sixth exemplary embodiment is a copper filament precipitating variable resistance element. When “copper filament”, reaching the upper surface of the copper wiring 608 of the copper wiring layer 610 in the lower layer from the lower surface of the first electrode 604, is generated in the variable resistance film 603 formed of the solid electrolyte, the “low resistive” state is achieved, whereby the “ON” state is achieved. When the “copper filament” generated in the variable resistance film 603 is dissolved so that electrical connection between the lower surface of the first electrode 604 and the upper surface of the copper wiring 608 of the copper wiring layer 610 in the lower layer is cut off, the “high resistive state” is achieved, whereby the “OFF” state is achieved.

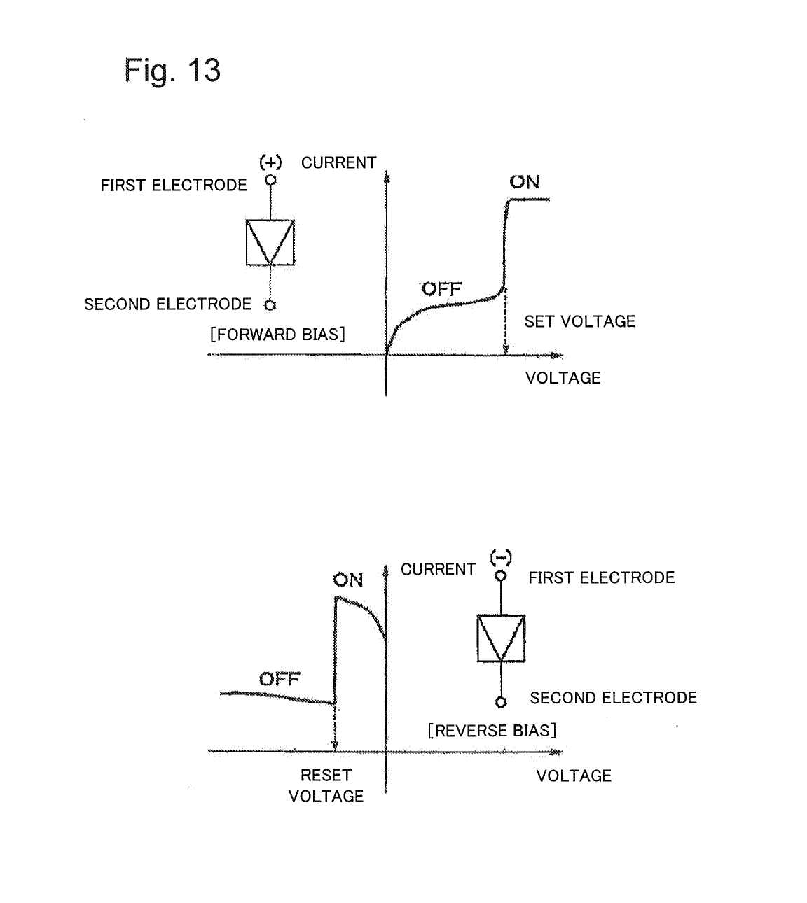

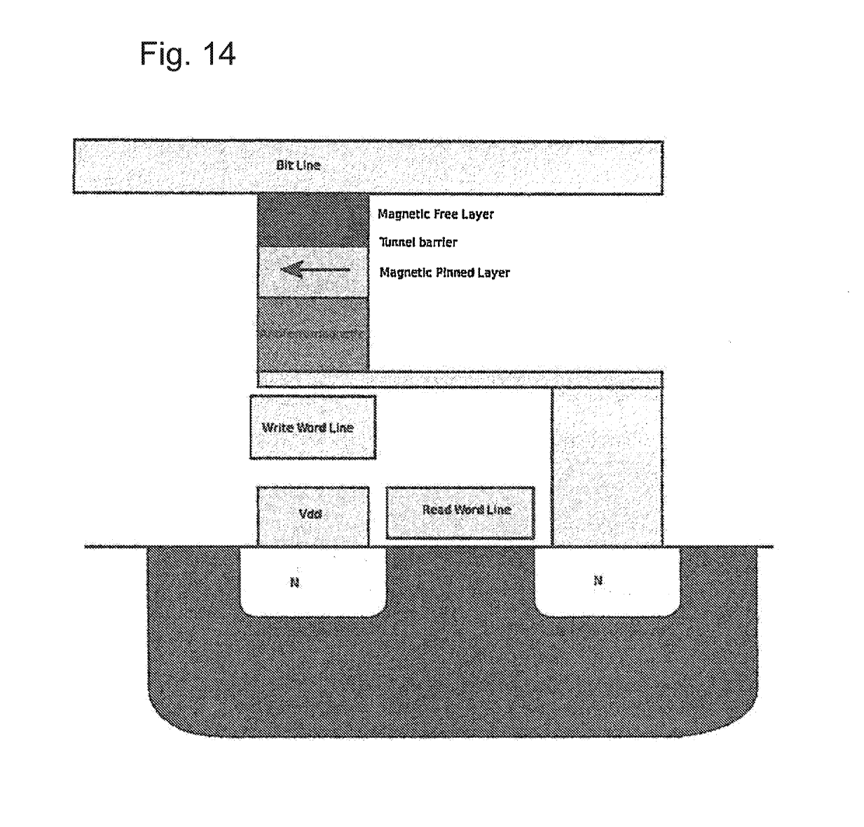

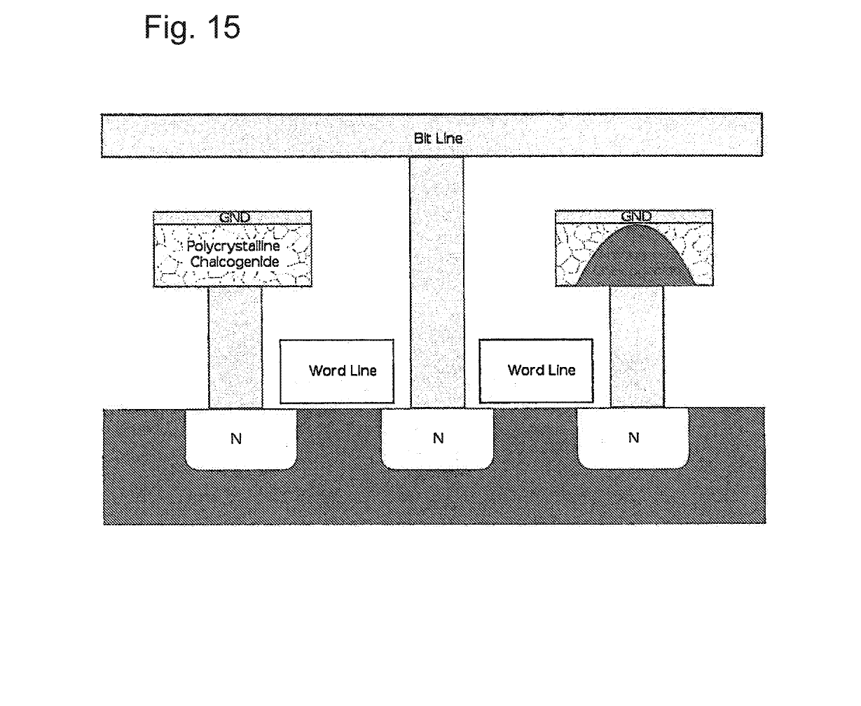

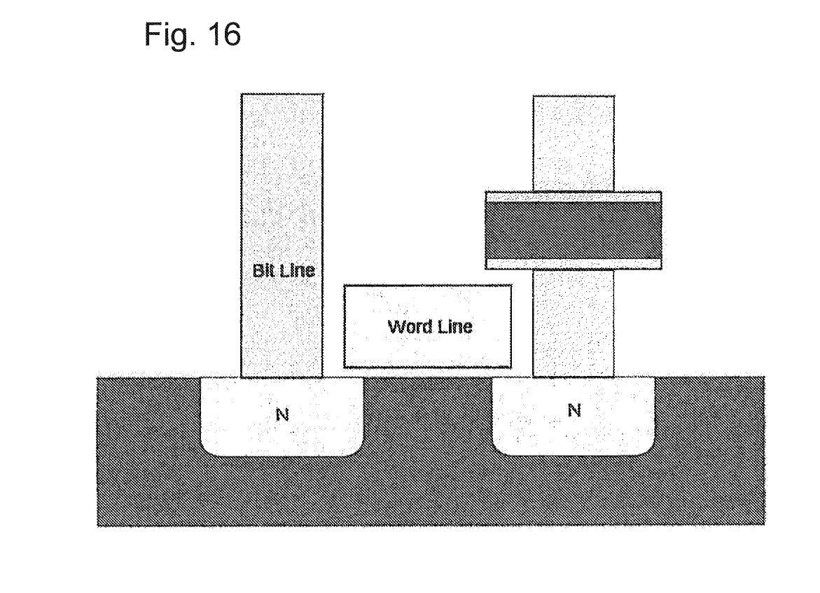

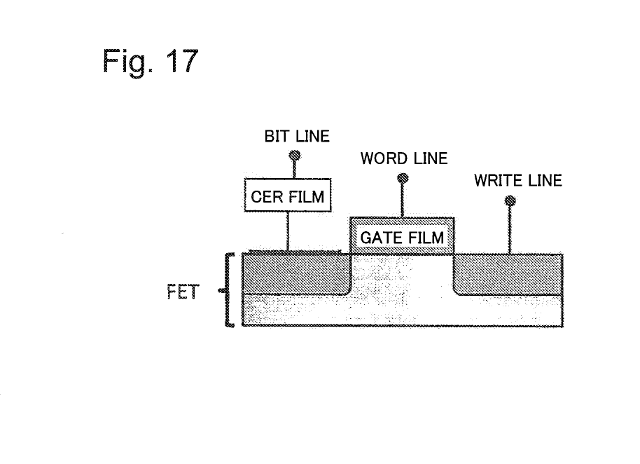

In a generation process for the “copper filament” (set process), for example, as exemplarily illustrated in an upper side of in FIG. 13, the “second electrode” is grounded and a positive voltage is applied to the “first electrode”. Thus, the “applied positive voltage” induces ionization (oxidation) reaction in a boundary between the copper wiring 608 of the copper wiring layer 610 in the lower layer and the variable resistance film 603 formed of the solid electrolyte, whereby copper ions are generated from copper. The copper ions thus generated are moved from a side of the “first electrode” to a side of the “second electrode” by an electric field in the variable resistance film 603 formed of the solid electrolyte. On the side of the “second electrode”, electrons are provided to the copper ions to cause reduction reaction from the copper ions to copper, whereby the copper precipitation proceeds. The generation of the “copper filament” is achieved by the precipitating copper. When the precipitating copper generates “protrusions” on the surface of the “second electrode”, the electrons are preferentially supplied to the “protrusion” portions where the electric fields are concentrated. As a result, the copper precipitation preferentially occurs at the distal ends of the “protrusion” portions. As a result, the “copper filament” grows from the “protrusion” portions, generated on the surface of the “second electrode”.

The diameter of the “copper filament” expands along with the movement of the distal end of the “copper filament” growing from the side of the “second electrode” toward the surface of the “first electrode”. When the distal end of the growing “copper filament” reaches the surface of the “first electrode”, the current flowing through the “copper filament” replaces the “ion conducted current” by the “ion conduction” with the copper ions in the solid electrolyte, and thus state rapidly transitions to the “low resistive state”.

In an elution process for the “copper filament” (reset process), as exemplarily illustrated in a lower side of FIG. 13, the “second electrode” is grounded and a negative voltage is applied to the “first electrode”. Thus, the “applied negative voltage” induces ionization (oxidation) reaction in a boundary between the “copper filament” and the variable resistance film 603 formed of the solid electrolyte, whereby copper ions are generated from copper. The copper ions thus generated are moved to the side of the “first electrode” by an electric field in the variable resistance film 603 formed of the solid electrolyte. On the side of the “first electrode”, electrons are provided to the copper ions to cause reduction reaction from the copper ions to copper, whereby the copper re-precipitation proceeds. The copper ion elution on the “copper filament” surface preferentially proceeds at the distal end portions of the “copper filament” where the electric fields are concentrated. Thus, the distal end of the “copper filament”, which has reached the surface of the “first electrode”, dissolves to cut off the current flowing through the “copper filament”, leaving only the “ion conducted current” by “ion conduction” with the copper ions in the solid electrolyte. The copper ions preferentially elute on the surface of the “copper filament” where the electric fields are concentrated, whereby the elution of the “copper filament” rapidly proceeds. As a result, the state transitions to the “high resistive” state.

The precipitation process for the “copper filament” can be explained by the following model formula representing the oxidation of copper into copper ions and migration of copper ions into the “variable resistance film” 603 caused by an electric field applied to the boundary between the copper wiring 608 of the copper wiring layer 610 in the lower layer and the variable resistance film 603 composed of a solid electrolyte.

t=α·E⁻γ·exp(Eₐ/kT)

t: a period of time until a resistance change takes place (the distal end of the “copper filament” reaches the surface of the copper wiring 608);

E: electric field (an electric field originally applied to the solid electrolyte);

H: humidity (the concentration of water in the gas phase in contact with the solid electrolyte);

Ea: activation energy (activation energy in the ionization process of metal Cu into copper ions Cu²⁺);

k: Boltzmann constant, T: temperature (temperature at the boundary between the copper wiring 608 and the variable resistance film 603)

This model shows that the resistance change operation (switching operation) of the “variable resistance element” depends not only on the operating voltage (electric field E) but also depends largely on the humidity H (the concentration of water in the gas phase in contact with the solid electrolyte). Specifically, when the humidity H (the concentration of water in the gas phase in contact with the solid electrolyte) changes as the operating environment changes, the time t required for completing the resistance change operation (switching operation) of the “variable resistance element” also changes. In other words, to maintain a constant time t required for completing the resistance change operation (switching operation) of the “variable resistance element”, (Eγ·Hⁿ) needs to be kept constant. Since the humidity H (the concentration of water in the gas phase in contact with the solid electrolyte) changes as the operating environment changes, the threshold voltage (threshold electric field Eₜₕ) of the resistance change operation (switching operation) fluctuates for completing the resistance change operation (switching operation) in the specific time t. The fluctuation in the threshold voltage (threshold electric field Eₜₕ) of the resistance change operation (switching operation) can cause false operation of the “variable resistance element”. To prevent the false operation of the “variable resistance element”, it is necessary to cover the side surfaces of the “variable resistance film” 603 with a “passivation film”, i.e., the protective insulation film 606, which prevents the “variable resistance film” 603 of the “variable resistance element” from contacting water in a surrounding environment, whereby the “variable resistance film” 603 can be protected from water.

(First Mode)

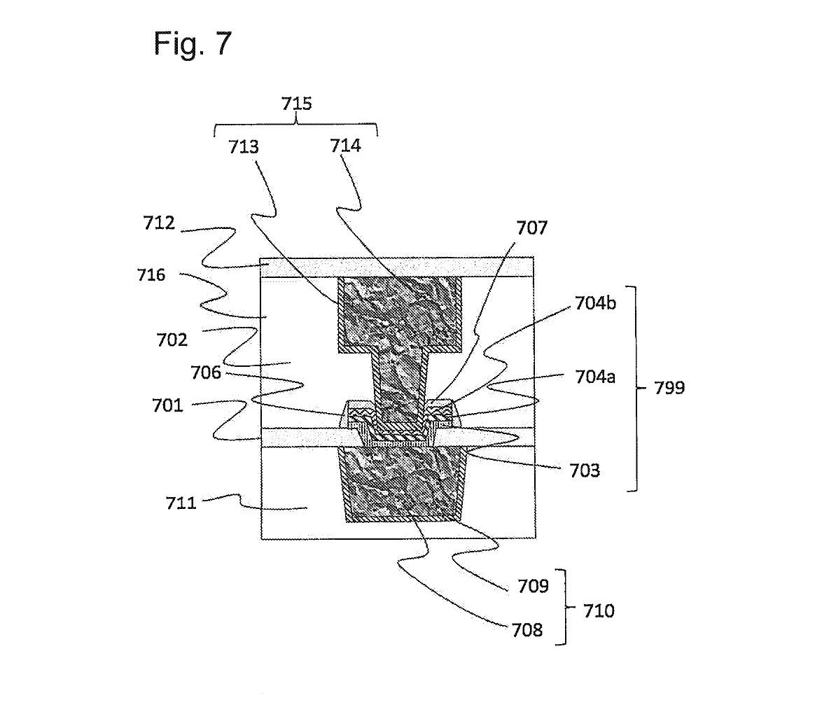

An example of a mode of the semiconductor device, in which the variable resistance element according to the third exemplary embodiment of the present invention is used as a non-volatile switching element provided in a multi-layered wiring layer, is described with reference to the drawings. FIG. 7 is a cross-sectional view schematically illustrating a first mode of the variable resistance element according to the third exemplary embodiment of the present invention, used as the non-volatile switching element provided in the multi-layered wiring layer of the semiconductor device.

The variable resistance element of the first mode illustrated in FIG. 7 is formed in a mode of a two-terminal solid electrolyte switch.

A variable resistance element 799 illustrated in FIG. 7 uses a copper wiring 708 of a copper wiring layer (first copper wiring) 710 in a lower layer as the “first electrode” that functions as the “ion supplying layer”. A variable resistance film 703 is formed of a solid electrolyte and functions as the “ion conducting layer”. A “first electrode” 704, in contact with an upper surface of the variable resistance film 703, has a stacked structure including a first upper electrode 704a and a second upper electrode 704b. The first upper electrode 704a in the “first electrode” 704 is in contact with the upper surface of the variable resistance film 703. The upper surface of the “first electrode” 704, that is, the upper surface of the second upper electrode 704b is provided with an upper surface protection film 707.

The variable resistance film 703 and the “first electrode” 704 of the variable resistance element 799 are formed on the upper surface of a first interlayer insulation film 701.

The variable resistance film 703 is in contact with a surface of a copper wiring 708 of a copper wiring layer (first copper wiring) 710 in the lower layer via a hole opened in the first interlayer insulation film 701. Thus, in a portion of the opened hole, the lower surface of the variable resistance film 703 is in contact with the “first electrode” that functions as the “ion supplying layer” and the upper surface of the variable resistance film 703 is in contact with the first electrode 704 that functions as the “second electrode”. Thus, the variable resistance element 799 forms the copper filament deposition variable resistance element.

The side surfaces of the variable resistance film 703, the first upper electrode 704a, the second upper electrode 704b, and the upper surface protection film 707 are covered with a protective insulation film 706. As a result, at least the side surfaces of the variable resistance film 703, the first upper electrode 704a, and the second upper electrode 704b are covered with the protective insulation film 706, and the upper surface of the second upper electrode 704b is covered with the upper surface protection film 707.

For example, as the solid electrolyte used for forming the variable resistance film 703, an organic polymer film including SiO is preferably selected. The first upper electrode 704a may be formed by using Ru, and the second upper electrode 704b may be formed by using Ta or TaN.

The upper surface protection film 707 and the protective insulation film 706 are preferably formed of the same material. The protective insulation film 706 and the upper surface protection film 707 are formed of an insulation film having functions of preventing the variable resistance film 703, the first upper electrode 704a, and the second upper electrode 704b from being oxidized by oxygen and preventing the entrance of water when the second interlayer insulation film 702 is formed. When an oxide film having ion conductivity is used as the solid electrolyte, forming the variable resistance film 703, the protective insulation film 706 is an insulation film having a function of preventing desorption of oxygen from the solid electrolyte. The protective insulation film 706 and the upper surface protection film 707 are preferably formed by using a SiN film, a SiCN film, or the like, for example.

The copper wiring layer (first copper wiring) 710 in the lower layer includes the copper wiring 708 embedded in a wiring trench formed in an interlayer insulation film 711 in the lower layer with barrier metal 709 provided in between. The first interlayer insulation film 701 is formed on the upper surface of the copper wiring layer (first copper wiring) 710 in the lower layer. The first interlayer insulation film 701 has a function as an insulating barrier film for preventing diffusion of copper from the upper surface of the copper wiring layer 710. A SiN film, a SiCN film, or the like is preferably used for forming the first interlayer insulation film 701, to provide the function as the insulating barrier film.

The second interlayer insulation film 702 is in direct contact with the first interlayer insulation film 701. A copper wiring layer (second copper wiring) 715 in an upper layer is formed in the second interlayer insulation film 702. The copper wiring layer (second copper wiring) 715 in the upper layer includes a copper wiring 714 embedded via barrier metal 713 in a wiring trench and a via hole, formed in the second interlayer insulation film 702. The via hole provided in the copper wiring layer (second copper wiring) 715 in the upper layer communicates with the second upper electrode 704b through an opening formed in the upper surface protection film 707.

A SiO₂ film, a SiOC film, a SiOCH film, a low dielectric constant film, or the like may be used for forming the second interlayer insulation film 702.

The surface of the copper wiring layer (second copper wiring) 715 in the upper layer is covered with an insulating barrier film 712, for preventing diffusion of copper from the copper wiring 714 of the copper wiring layer (second copper wiring) 715 in the upper layer. A SiN film, a SiCN film, or the like is preferably used for forming the insulating barrier film 712 as in the case of the first interlayer insulation film 701.

The barrier metal 709 for the copper wiring layer (first copper wiring) 710 in the lower layer is a conductive film, having a barrier property, and covers the side and bottom surfaces of the copper wiring 708 to prevent the copper, as the main component of the copper wiring 708 of the copper wiring layer (first copper wiring) 710 in the lower layer, from diffusing into the interlayer insulation film 711 in the lower layer. Similarly, the barrier metal 713 for the copper wiring layer (second copper wiring) 715 in the lower layer is a conductive film, having a barrier property, and covers the side and bottom surfaces of the copper wiring 714 to prevent the copper, as the main component of the copper wiring 714 of the copper wiring layer (first copper wiring) 715 in the upper layer, from diffusing into the second interlayer insulation film 702 and the second upper electrode 704b in communication with the via hole.

As the conductive film having the barrier property against the diffusion of copper, for example, refractory metal or nitride of the same such as tantalum (Ta), tantalum nitride (TaN), titanium nitride (TiN), tungsten carbonitride (WCN), or a stacked film of these is used for the barrier metal 709 for the copper wiring layer (first copper wiring) 710 in the lower layer and the barrier metal 713 for the copper wiring layer (second copper wiring) 715 in the lower layer.

(Second Mode)

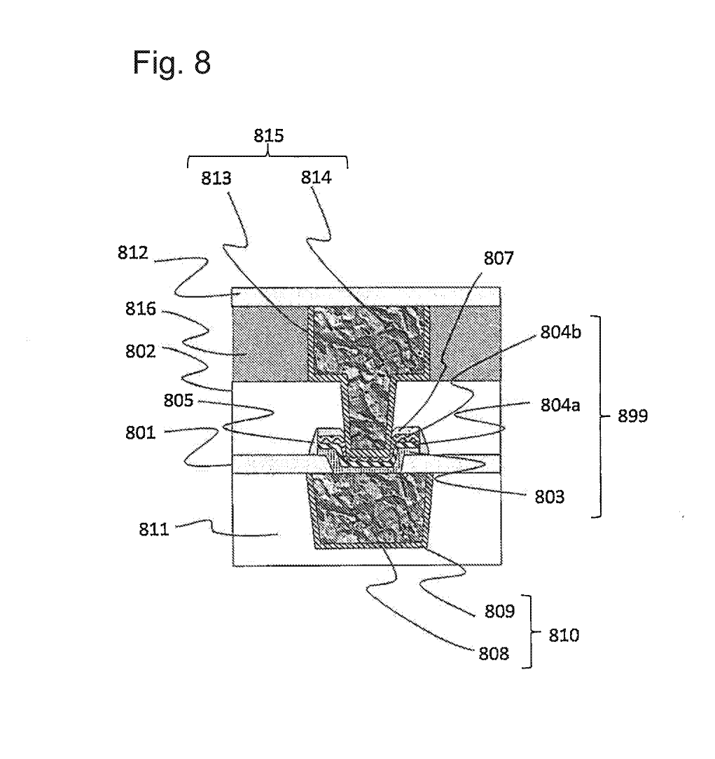

An example of a mode of the semiconductor device, in which the variable resistance element according to the third exemplary embodiment of the present invention is used as a non-volatile switching element provided in a multi-layered wiring layer, is described with reference to the drawings. FIG. 8 is a cross-sectional view schematically illustrating a second mode of the variable resistance element according to the third exemplary embodiment of the present invention, used as the non-volatile switching element provided in the multi-layered wiring layer of the semiconductor device.

The variable resistance element of the second mode illustrated in FIG. 8 is formed in a mode of a two-terminal solid electrolyte switch.

A variable resistance element 899 illustrated in FIG. 8 uses a copper wiring 808 of a copper wiring layer (first copper wiring) 810 in a lower layer as the “first electrode” that functions as the “ion supplying layer”. A variable resistance film 803 is formed of a solid electrolyte and functions as the “ion conducting layer”. A “first electrode” 804, in contact with an upper surface of the variable resistance film 803, has a stacked structure including a first upper electrode 804a and a second upper electrode 804b. The first upper electrode 804a in the “first electrode” 804 is in contact with the upper surface of the variable resistance film 803. The upper surface of the “first electrode” 804, that is, the upper surface of the second upper electrode 804b is provided with an upper surface protection film 807.

The variable resistance film 803 and the “first electrode” 804 of the variable resistance element 899 are formed on the upper surface of a first interlayer insulation film 801.

The variable resistance film 803 is in contact with a surface of a copper wiring 808 of a copper wiring layer (first copper wiring) 810 in the lower layer via a hole opened in the first interlayer insulation film 801. Thus, in a portion of the opened hole, the lower surface of the variable resistance film 803 is in contact with the “first electrode” that functions as the “ion supplying layer”, and the upper surface of the variable resistance film 803 is in contact with the first electrode 804 that functions as the “second electrode”. Thus, the variable resistance element 899 forms the copper filament deposition variable resistance element.

The side surfaces of the variable resistance film 803, the first upper electrode 804a, the second upper electrode 804b, and the upper surface protection film 807 are covered with a protective insulation film 806. As a result, at least the side surfaces of the variable resistance film 803, the first upper electrode 804a, and the second upper electrode 804b are covered with the protective insulation film 806, and the upper surface of the second upper electrode 804b is covered with the upper surface protection film 807.

For example, it is preferable to select an organic polymer film including SiO, as the solid electrolyte used for forming the variable resistance film 803. The first upper electrode 804a may be formed by using Ru, and the second upper electrode 804b may be formed by using Ta or TaN.

The upper surface protection film 807 and the protective insulation film 806 are preferably formed of the same material. The protective insulation film 806 and the upper surface protection film 807 are formed of an insulation film having functions of preventing the variable resistance film 803, the first upper electrode 804a, and the second upper electrode 804b from being oxidized by oxygen when the second interlayer insulation film 802 is formed and of preventing the entrance of water. When an oxide film having ion conductivity is used as the solid electrolyte, forming the variable resistance film 803, the protective insulation film 806 is an insulation film having a function of preventing desorption of oxygen from the solid electrolyte. The protective insulation film 806 and the upper surface protection film 807 are preferably formed by using a SiN film, a SiCN film, or the like, for example.

The copper wiring layer (first copper wiring) 810 in the lower layer includes the copper wiring 808 embedded via barrier metal 809 in a wiring trench formed in an interlayer insulation film 811 in the lower layer. The first interlayer insulation film 801 is formed on the upper surface of the copper wiring layer (first copper wiring) 810 in the lower layer. The first interlayer insulation film 801 has a function also as an insulating barrier film for preventing diffusion of copper from the upper surface of the copper wiring layer 810. A SiN film, a SiCN film, or the like is preferably used for forming the first interlayer insulation film 801, to provide the function as the insulating barrier film.

The second interlayer insulation film 802 is in direct contact with the first interlayer insulation film 801. A third interlayer insulation film 816 is formed above the second interlayer insulation film 802. The third interlayer insulation film 816 is in direct contact with the second interlayer insulation film 802.

A copper wiring layer (second copper wiring) 815 in an upper layer is formed in the third interlayer insulation film 816. The copper wiring layer (second copper wiring) 815 formed in the third interlayer insulation film 816 is integrally formed with a via portion formed in the second interlayer insulation film 802. The copper wiring layer (second copper wiring) 815 and the via portion include a copper wiring 814 embedded via barrier metal 813 in a wiring trench formed in the third interlayer insulation film 816 and a via hole formed in the second interlayer insulation film 802. The via hole provided in the copper wiring layer (second copper wiring) 815 in the upper layer communicates with the second upper electrode 804b through an opening formed in the upper surface protection film 807.

The surface of the copper wiring layer (second copper wiring) 815 in the upper layer is covered with an insulating barrier film 812, for preventing diffusion of copper from the copper wiring 814 of the copper wiring layer (second copper wiring) 815 in the upper layer. A SiN film, a SiCN film, or the like is preferably used for forming the insulating barrier film 812, as in the case of the first interlayer insulation film 801.

The barrier metal 809 for the copper wiring layer (first copper wiring) 810 in the lower layer is a conductive film, having a barrier property, and covers the side and bottom surfaces of the copper wiring 808 to prevent the copper, as the main component of the copper wiring 808 of the copper wiring layer (first copper wiring) 810 in the lower layer, from diffusing into the interlayer insulation film 811 in the lower layer. Similarly, the barrier metal 813 for the copper wiring layer (second copper wiring) 815 in the lower layer is a conductive film, having a barrier property, and covers the side and bottom surfaces of the copper wiring 814 to prevent the copper, as the main component of the copper wiring 814 of the copper wiring layer (first copper wiring) 815 in the upper layer, from diffusing into the third interlayer insulation film 816, the second interlayer insulation film 802, and the second upper electrode 804b in communication with the via hole.

As the conductive film having the barrier property against the diffusion of copper, for example, refractory metal or nitride of the same such as tantalum (Ta), tantalum nitride (TaN), titanium nitride (TiN), tungsten carbonitride (WCN), or a stacked film of these is used for the barrier metal 809 for the copper wiring layer (first copper wiring) 810 in the lower layer and is used for the barrier metal 813 for the copper wiring layer (second copper wiring) 815 in the lower layer.

In the variable resistance element of the second mode illustrated in FIG. 8, the second interlayer insulation film 802 and the third interlayer insulation film 816 are formed of different insulating materials. The third interlayer insulation film 816 and the insulating barrier film 812 are formed of different insulating materials. Similarly, the interlayer insulation film 811 in the lower layer and the first interlayer insulation film 801 that functions as the insulating barrier film are formed of different insulating materials. The first interlayer insulation film 801 and the second interlayer insulation film 802 are formed of different insulating materials.

As described above, a SiN film, a SiCN film, or the like is preferably used for forming the first interlayer insulation film 801, which functions as the insulating barrier film, and the insulating barrier film 812.

In this case, the interlayer insulation film 811 in the lower layer may be formed by using a SiO₂ film, a SiOC film, a SiOCH film, a low dielectric constant film, and the like.

A SiN film and a SiCN film that are used for manufacturing the protective insulation film 806 and the upper surface protection film 807 for example, have no oxygen permeability or water permeability, and thus protects the variable resistance film 803, the first upper electrode 804a, and the second upper electrode 804b during the process of forming the second interlayer insulation film 802.

In this case, an insulating material with a smaller relative-dielectric constant than the SiN film and the SiCN film, used for manufacturing the first interlayer insulation film 801, the protective insulation film 806, and the upper surface protection film 807 for example, is preferably selected as an insulating material used for forming the second interlayer insulation film 802. An insulating material with a smaller relative-dielectric constant than the insulating material used for manufacturing the second interlayer insulation film 802, is preferably selected as an insulating material used for forming the third interlayer insulation film 816.

Thus, the relative dielectric constants are preferably set to satisfy the following condition: “the insulating material used for forming the first interlayer insulation film 801”>the insulating material used for forming the second interlayer insulation film 802”>“the insulating material used for forming the third interlayer insulation film 816”.

When a SiN film or a SiCN film for example is selected as an insulating material with a high relative-dielectric constant (k=7) as “the insulating material used for forming the first interlayer insulation film 801”,

a SiO₂ film for example, as an insulating material with a medium relative-dielectric constant of about (k=3.5 to 4.5) is preferably selected as “the insulating material used for forming the second interlayer insulation film 802”, and

a SiOCH film for example, as an insulating material with a low relative-dielectric constant of about (k=2.5 to 3.5) is preferably selected as “the insulating material used for forming the third interlayer insulation film 816”.

Through the selections described above, “the insulating material used for forming the second interlayer insulation film 802” further provides an effect of lowering hygroscopicity.

The “insulating material used for manufacturing the protective insulation film 806 and the upper surface protection film 807” is preferably a film finer than “the insulating material used for forming the first interlayer insulation film 801”, so that overwhelming “protection” characteristics can be achieved. To satisfy this condition, the insulating materials are selected in such a manner that the relative dielectric constant of the “insulating material used for manufacturing the protective insulation film 806 and the upper surface protection film 807” exceeds the relative dielectric constant of the “insulating material used for forming the first interlayer insulation film 801”. For example, a SiN film is preferably used for forming the “insulating material used for manufacturing the protective insulation film 806 and the upper surface protection film 807”, and a SiCN film is preferably used for forming the “insulating material used for forming the first interlayer insulation film 801”.

(Third Mode)

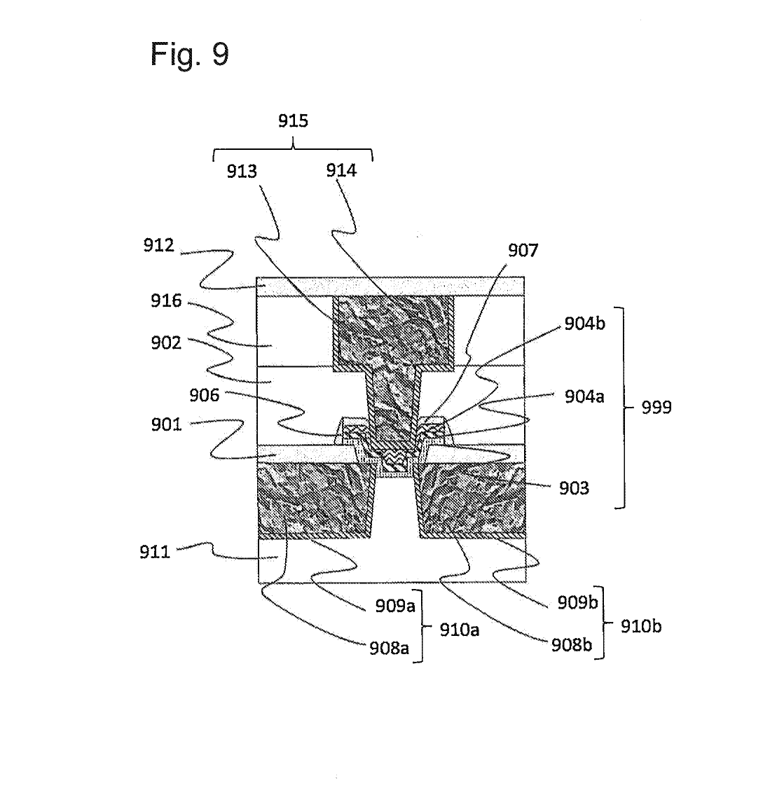

An example of a mode of the semiconductor device, in which the variable resistance element according to the third exemplary embodiment of the present invention is used as a non-volatile switching element provided in a multi-layered wiring layer, is described with reference to the drawings. FIG. 9 is a cross-sectional view schematically illustrating a third mode of the variable resistance element according to the third exemplary embodiment of the present invention, used as the non-volatile switching element provided in the multi-layered wiring layer of the semiconductor device.

The variable resistance element of the third mode illustrated in FIG. 9 is formed in a mode of a three-terminal solid electrolyte switch.

A variable resistance element 999 illustrated in FIG. 9 uses each of two copper wirings including a copper wiring 908a of a copper wiring layer (first copper wiring) 910a in a lower layer and a copper wiring 908b of a copper wiring layer (first copper wiring) 910b in the lower layer, as “first electrodes” that functions as “the ion supplying layers”. Thus, the three-terminal solid electrolyte switch is formed. A variable resistance film 903 is formed of a solid electrolyte and functions as “the ion conducting layer”. A “first electrode” 904, in contact with an upper surface of the variable resistance film 903, has a stacked structure including a first upper electrode 904a and a second upper electrode 904b. The first upper electrode 904a in the “first electrode” 904 is in contact with the upper surface of the variable resistance film 903. The upper surface of the “first electrode” 904, that is, the upper surface of the second upper electrode 904b is provided with an upper surface protection film 907.

The variable resistance film 903 and the “first electrode” 904 of the variable resistance element 999 are formed on the upper surface of a first interlayer insulation film 901.

The variable resistance film 903 is in contact with a surface of the copper wiring 908a of the copper wiring layer (first copper wiring) 910a in the lower layer and the copper wiring 908b of the copper wiring layer (first copper wiring) 910b via a hole opened in the first interlayer insulation film 901. Thus, in a portion of the opened hole, the lower surface of the variable resistance film 903 is in contact with the “first electrode” that functions as the “ion supplying layer”, that is, the copper wiring 908a of the copper wiring layer (first copper wiring) 910a and the copper wiring 908b of the copper wiring layer (first copper wiring) 910b in the lower layer, and the upper surface of the variable resistance film 903 is in contact with the first electrode 904 that functions as the “second electrode”. Thus, the variable resistance element 999 forms the three-terminal solid electrolyte switch having a configuration in which two “copper filament deposition variable resistance elements” are connected in parallel through the “second electrode”.

The side surfaces of the variable resistance film 903, the first upper electrode 904a, the second upper electrode 904b, and the upper surface protection film 907 are covered with a protective insulation film 906. As a result, at least the side surfaces of the variable resistance film 903, the first upper electrode 904a, and the second upper electrode 904b are covered with the protective insulation film 906, and the upper surface of the second upper electrode 904b is covered with the upper surface protection film 907.

For example, it is preferable to select an organic polymer film including SiO, as the solid electrolyte used for forming the variable resistance film 903. The first upper electrode 904a may be formed by using Ru, and the second upper electrode 904b may be formed by using Ta or TaN.

The upper surface protection film 907 and the protective insulation film 906 are preferably formed of the same material. The protective insulation film 906 and the upper surface protection film 907 are formed of insulation film having functions of preventing the variable resistance film 903, the first upper electrode 904a, and the second upper electrode 904b from being oxidized by oxygen when the second interlayer insulation film 902 is formed and of preventing the entrance of water. When an oxide film having ion conductivity is used as the solid electrolyte, forming the variable resistance film 903, the protective insulation film 906 is an insulation film having a function of preventing desorption of oxygen from the solid electrolyte. The protective insulation film 906 and the upper surface protection film 907 are preferably formed by using a SiN film, a SiCN film, or the like, for example.

The copper wiring layer (first copper wiring) 910a in the lower layer includes the copper wiring 908a embedded via barrier metal 909a in a first wiring trench formed in an interlayer insulation film 911 in the lower layer. The copper wiring layer (first copper wiring) 910b in the lower layer includes the copper wiring 908b embedded via barrier metal 909b in a second wiring trench formed in an interlayer insulation film 911 in the lower layer. The first interlayer insulation film 901 is formed on the upper surfaces of the copper wiring layer (first copper wiring) 910a and the copper wiring layer (first copper wiring) 910b in the lower layer. The first interlayer insulation film 901 has a function also as an insulating barrier film for preventing diffusion of copper from the upper surfaces of the copper wiring layer (first copper wiring) 910a and the copper wiring layer (first copper wiring) 910b in the lower layer. A SiN film, a SiCN film, or the like is preferably used for forming the first interlayer insulation film 901, to provide the function as the insulating barrier film.

The second interlayer insulation film 902 is in direct contact with the first interlayer insulation film 901. A third interlayer insulation film 916 is formed above the second interlayer insulation film 902. The third interlayer insulation film 916 is in direct contact with the second interlayer insulation film 902.

A copper wiring layer (second copper wiring) 915 in an upper layer is formed in the third interlayer insulation film 916. The copper wiring layer (second copper wiring) 915 formed in the third interlayer insulation film 916 is integrally formed with a via portion formed in the second interlayer insulation film 902. The copper wiring layer (second copper wiring) 915 and the via portion include a copper wiring 914 embedded via barrier metal 913 in a wiring trench formed in the third interlayer insulation film 916 and a via hole formed in the second interlayer insulation film 902. The via hole provided in the copper wiring layer (second copper wiring) 915 in the upper layer communicates with the second upper electrode 904b through an opening formed in the upper surface protection film 907.

The surface of the copper wiring layer (second copper wiring) 915 in the upper layer is covered with an insulating barrier film 912 for preventing diffusion of copper from the copper wiring 914 of the copper wiring layer (second copper wiring) 915 in the upper layer. A SiN film, a SiCN film, or the like is preferably used for forming the insulating barrier film 912 as in the case of the first interlayer insulation film 901.

The barrier metal 909a for the copper wiring layer (first copper wiring) 910a in the lower layer is a conductive film, having a barrier property, and covers the side and bottom surfaces of the copper wiring 908a to prevent the copper, as the main component of the copper wiring 908a of the copper wiring layer (first copper wiring) 910a in the lower layer, from diffusing into the interlayer insulation film 911 in the lower layer. The barrier metal 909b for the copper wiring layer (first copper wiring) 910b in the lower layer is a conductive film, having a barrier property, and covers the side and bottom surfaces of the copper wiring 908b to prevent the copper, as the main component of the copper wiring 908b of the copper wiring layer (first copper wiring) 910b in the lower layer, from diffusing into the interlayer insulation film 911 in the lower layer. Similarly, the barrier metal 913 for the copper wiring layer (second copper wiring) 915 in the lower layer is a conductive film, having a barrier property, and covers the side and bottom surfaces of the copper wiring 914 to prevent the copper, as the main component of the copper wiring 914 of the copper wiring layer (first copper wiring) 915 in the upper layer, from diffusing into the third interlayer insulation film 916, the second interlayer insulation film 902, and the second upper electrode 904b in communication with the via hole.

As the conductive film having the barrier property against the diffusion of copper, for example, refractory metal or nitride of the same such as tantalum (Ta), tantalum nitride (TaN), titanium nitride (TiN), tungsten carbonitride (WCN), or a stacked film of these is used for the barrier metal 909a for the copper wiring layer (first copper wiring) 910a in the lower layer, the barrier metal 909b for the copper wiring layer (first copper wiring) 910b in the lower layer, and the barrier metal 913 for the copper wiring layer (second copper wiring) 915 in the lower layer.

Also in the variable resistance element of the third mode illustrated in FIG. 9, the second interlayer insulation film 902 and the third interlayer insulation film 916 are formed of different insulating materials. The third interlayer insulation film 916 and the insulating barrier film 912 are formed of different insulating materials. Similarly, the interlayer insulation film 911 in the lower layer and the first interlayer insulation film 901 that functions as the insulating barrier film are formed of different insulating materials. The first interlayer insulation film 901 and the second interlayer insulation film 902 are formed of different insulating materials.

As described above, a SiN film, a SiCN film, or the like is preferably used for forming the first interlayer insulation film 901 that functions as the insulating barrier film and the insulating barrier film 912.

In this case, the interlayer insulation film 911 in the lower layer may be formed by using a SiO₂ film, a SiOC film, a SiOCH film, a low dielectric constant film, and the like.

A SiN film and a SiCN film that are used for manufacturing the protective insulation film 906 and the upper surface protection film 907 for example, have no oxygen permeability or water permeability, and thus protects the variable resistance film 903, the first upper electrode 904a, and the second upper electrode 904b in the process of forming the second interlayer insulation film 902.

In this case, an insulating material with a smaller relative-dielectric constant than the SiN film and the SiCN film used for manufacturing the first interlayer insulation film 901, the protective insulation film 906, and the upper surface protection film 907 for example, is preferably selected as an insulating material used for forming the second interlayer insulation film 902. An insulating material with a smaller relative-dielectric constant than the insulating material, used for manufacturing the second interlayer insulation film 902 is preferably selected as an insulating material used for forming the third interlayer insulation film 916.

Thus, the relative dielectric constants are preferably set to satisfy the following condition: “the insulating material used for forming the first interlayer insulation film 901”>the insulating material used for forming the second interlayer insulation film 902”>“the insulating material used for forming the third interlayer insulation film 916”.

When a SiN film or a SiCN film for example is selected as an insulating material with a high relative-dielectric constant (k=7) as “the insulating material used for forming the first interlayer insulation film 901”,

a SiO₂ film for example, as an insulating material with a medium relative-dielectric constant of about (k=3.5 to 4.5) is preferably selected as “the insulating material used for forming the second interlayer insulation film 902”, and

a SiOCH film for example, as an insulating material with a low relative-dielectric constant of about (k=2.5 to 3.5) is preferably selected as “the insulating material used for forming the third interlayer insulation film 916”.

Through the selections described above, “the insulating material used for forming the second interlayer insulation film 902” further provides an effect of lowering hygroscopicity.

The “insulating material used for manufacturing the protective insulation film 906 and the upper surface protection film 907” is preferably a film finer than “the insulating material used for forming the first interlayer insulation film 901”, so that overwhelming “protection” characteristics can be achieved. To satisfy this condition, the insulating materials are selected in such a manner that the relative dielectric constant of the “insulating material used for manufacturing the protective insulation film 906 and the upper surface protection film 907” exceeds the relative dielectric constant of the “insulating material used for forming the first interlayer insulation film 901”. For example, a SiN film is preferably used for as the “insulating material used for manufacturing the protective insulation film 906 and the upper surface protection film 907”, and a SiCN film is preferably used as the “insulating material used for forming the first interlayer insulation film 901”.

As illustrated in FIG. 9, in a hole area formed in the first interlayer insulation film 901, the copper wiring layer (first copper wiring) 910a and the copper wiring layer (first copper wiring) 910b in the lower layer, as well as the interlayer insulation film 911 in the lower layer are exposed. In a process of forming the hole in the first interlayer insulation film 901, the interlayer insulation film 911 in the lower layer is partially etched to be removed, and thus a recess is formed. The variable resistance film 903 is formed to bury the recess.

The variable resistance film 903 formed in the recess is in contact with the barrier metal 909a for the copper wiring layer (first copper wiring) 910a in the lower layer or the barrier metal 909b for the copper wiring layer (first copper wiring) 910b in the lower layer. Here, a configuration, in which the variable resistance film 903 is sandwiched by the first electrode 904 that functions as the “second electrode” and the barrier metal 909a of the copper wiring layer (first copper wiring) 910a in the lower layer or the barrier metal 909b of the copper wiring layer (first copper wiring) 910b in the lower layer, does not function as a metal filament precipitating variable resistance element.

Thus, a configuration, in which the variable resistance film 903 is sandwiched by the first electrode 904 that functions as the “second electrode” and the copper wiring 908a of the copper wiring layer (first copper wiring) 910a in the lower layer and a configuration, in which the variable resistance film 903 is sandwiched by the first electrode 904 that functions as the “second electrode” and the copper wiring 908b of the copper wiring layer (first copper wiring) 910b each only function independently as “copper filament precipitating variable resistance element”. As exemplarily illustrated in FIG. 9, an area Sa of the portion where the variable resistance film 903 is sandwiched by the first electrode 904 that functions as the “second electrode” and the copper wiring 908a of the copper wiring layer (first copper wiring) 910a in the lower layer and an area Sb of the portion where the variable resistance film 903 is sandwiched by the first electrode 904 that functions as the “second electrode” and the copper wiring 908b of the copper wiring layer (first copper wiring) 910b in the lower layer may each independently be set. In other words, a resistance value of the “copper filament precipitating variable resistance element”, including the portion where the variable resistance film 903 is sandwiched by the first electrode 904 that functions as the “second electrode” and the copper wiring 908a of the copper wiring layer (first copper wiring) 910a in the lower layer, in the “ON” state and a resistance value of the “copper filament precipitating variable resistance element”, including the portion where the variable resistance film 903 is sandwiched by the first electrode 904 that functions as the “second electrode” and the copper wiring 908b of the copper wiring layer (first copper wiring) 910b in the lower layer, in the “ON” state may each independently be set.

The copper wiring layer (first copper wiring) 910a in the lower layer and the copper wiring layer (first copper wiring) 910b in the lower layer are electrically separated from each other, and thus can be independently provided with a voltage.

All things considered, the variable resistance element 999 of the third mode illustrated in FIG. 9 is the three-terminal solid electrolyte switch having the configuration in which the two “copper filament precipitating variable resistance elements” are connected in parallel through the “second electrode”. In this configuration, the two “copper filament precipitating variable resistance elements” may each independently be switched.

(Comparative Evaluation Result)

In the variable resistance element 999 of the third mode illustrated in FIG. 9, the side surfaces of the variable resistance film 903, the first upper electrode 904a, the second upper electrode 904b, and the upper surface protection film 907 are covered with the protective insulation film 906. Thus, the second interlayer insulation film 902 is in direct contact with the first interlayer insulation film 901. The third interlayer insulation film 916 is formed above the second interlayer insulation film 902. Here, the third interlayer insulation film 916 is in direct contact with the second interlayer insulation film 902

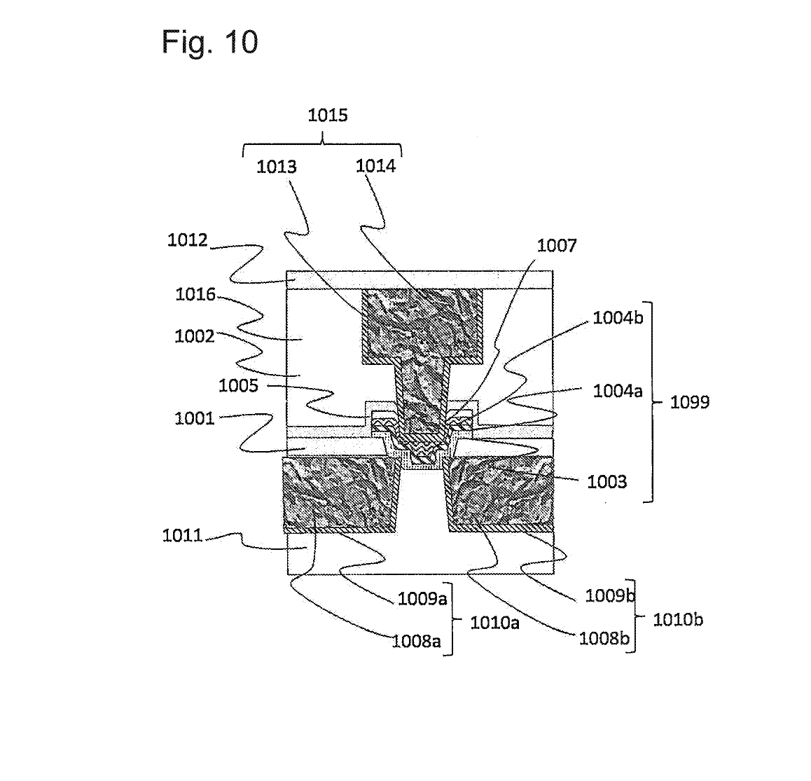

FIG. 10 is a cross-sectional view schematically illustrating a conventional variable resistance element used as the non-volatile switching element provided in the multi-layered wiring layer of the semiconductor device. The conventional variable resistance element illustrated in FIG. 10 is formed in a mode of a three-terminal solid electrolyte switch.

Also in a conventional variable resistance element 1099 illustrated in FIG. 10, side surfaces of a variable resistance film 1003, a first upper electrode 1004a, a second upper electrode 1004b, and an upper surface protection film 1007 are covered with a protective insulation film 1005.

The protective insulation film 1005 covers not only the side surfaces of the variable resistance film 1003, the first upper electrode 1004a, the second upper electrode 1004b, and the upper surface protection film 1007, but also covers the upper surfaces of the upper surface protection film 1007 and the first interlayer insulation film 1001.

A second interlayer insulation film 1002 is formed to cover the protective insulation film 1005. As a result, a state where the protective insulation film 1005 is interposed between the first interlayer insulation film 1001 and the second interlayer insulation film 1002 is achieved. The protective insulation film 1005, interposed between the first interlayer insulation film 1001 and the second interlayer insulation film 1002, has a film thickness of 20 nm.

A comparison evaluation was performed under the following conditions for the variable resistance element 999 of the third mode illustrated in FIG. 9 and the conventional variable resistance element 1099 illustrated in FIG. 10.

In the variable resistance element 999 of the third mode illustrated in FIG. 9 used in the comparison evaluation,

a SiCN film of relative dielectric constant k₁=4.9 was used as “the insulating material used for forming the first interlayer insulation film 901” and the film thickness of the first interlayer insulation film 901 was selected as d₁=30 nm;

a SiO₂ film of relative dielectric constant k₂=4.2 was used as “the insulating material used for forming the second interlayer insulation film 902” and the film thickness of the second interlayer insulation film 902 was selected as d₂=100 nm; and

a SiOCH film of relative dielectric constant k₃=2.7 was used as “the insulating material used for forming the interlayer insulation film 911 in the lower layer”.

Thus, an effective relative-dielectric constant k_{eff} of the “interlayer insulation film in the lower layer”, including the first interlayer insulation film 901, the second interlayer insulation film 902, and the interlayer insulation film 911 in the lower layer, was k_{eff}=3.15.

In the conventional variable resistance element 1099 illustrated in FIG. 10 used in the comparison evaluation,

a SiCN film of relative dielectric constant k₁=4.9 was used as “the insulating material used for forming the first interlayer insulation film 1001” and the film thickness of the first interlayer insulation film 1001 was selected as d₁=30 nm;

a SiN film of relative dielectric constant kₚ=7.0 was used as “the insulating material used for forming the protective insulation film 1005” and the film thickness of the protective insulation film 1005 was selected as dₚ=20 nm;

a SiO₂ film of relative dielectric constant k₂=4.2 was used as “the insulating material used for forming the second interlayer insulation film 1002” and the film thickness of the second interlayer insulation film 1002 was selected as d′₂=80 nm; and

a SiOCH film of relative dielectric constant k₃=2.7 was used as “the insulating material used for forming the interlayer insulation film 1011 in the lower layer”.

Thus, an effective relative-dielectric constant k_{eff} of the “interlayer insulation film in the lower layer”, including the first interlayer insulation film 1001, the protective insulation film 1005, the second interlayer insulation film 1002, and the interlayer insulation film 1011 in the lower layer, was k_{eff}=3.50.

To measure a capacity between wirings in the same layer, a comb type capacity measurement pattern with line/space=120 nm/120 nm was prepared.

In the variable resistance element 999 of the third mode illustrated in FIG. 9, the comb type capacity measurement patterns for the “first wiring” and the “second wiring”, corresponding to the copper wiring layer (first copper wiring) in the lower layer, were prepared in the interlayer insulation film 911 in the lower layer. A wiring height of “the wirings in the same layer” prepared in the interlayer insulation film 911 in the lower layer was selected as 150 nm.

In the conventional variable resistance element 1099 illustrated in FIG. 10, the comb type capacity measurement patterns for the “first wiring” and the “second wiring”, corresponding to the copper wiring layer (first copper wiring) in the lower layer, were prepared in the interlayer insulation film 1011 in the lower layer. A wiring height of “the wirings in the same layer” prepared in the interlayer insulation film 1011 in the lower layer was selected as 150 nm.

The capacity between the wirings in the same layer, that is, between the “first wiring” and the “second wiring” was measures by using the comb type capacity measurement pattern with line/space=120 nm/120 nm at 10 kHz.

In the conventional variable resistance element 1099 illustrated in FIG. 10, the capacity between the wirings in the same layer was 150 fF/mm.

In the variable resistance element 999 of the third mode illustrated in FIG. 9, the capacity between the wirings in the same layer was 135 fF/mm.

The capacity between the wirings of the variable resistance element 999 of the third mode illustrated in FIG. 9 was 10% lower than that of the conventional variable resistance element 1099 illustrated in FIG. 10.

Reliability of the variable resistance element was evaluated by PCT (Pressure Cooker Test) for 300 hours under the conditions of 120° C. and the humidity 100 RH %. Whether a “failure” was found was evaluated based on whether the “leak current” has increased with the variable resistance element being kept at the “high resistive state (OFF) state”.

No “failure” was found in both the variable resistance element 999 of the third mode illustrated in FIG. 9 and the conventional variable resistance element 1099 illustrated in FIG. 10 having the protective insulation film formed.

However, the increase in the “leak current” with the variable resistance element being kept at the “high resistive state (OFF)” was found in the evaluation on the reliability of the variable resistance element under the same condition on a “reference” variable resistance element as the conventional variable resistance element 1099 illustrated in FIG. 10 without the protective insulation film 1005.

(Fourth Mode)

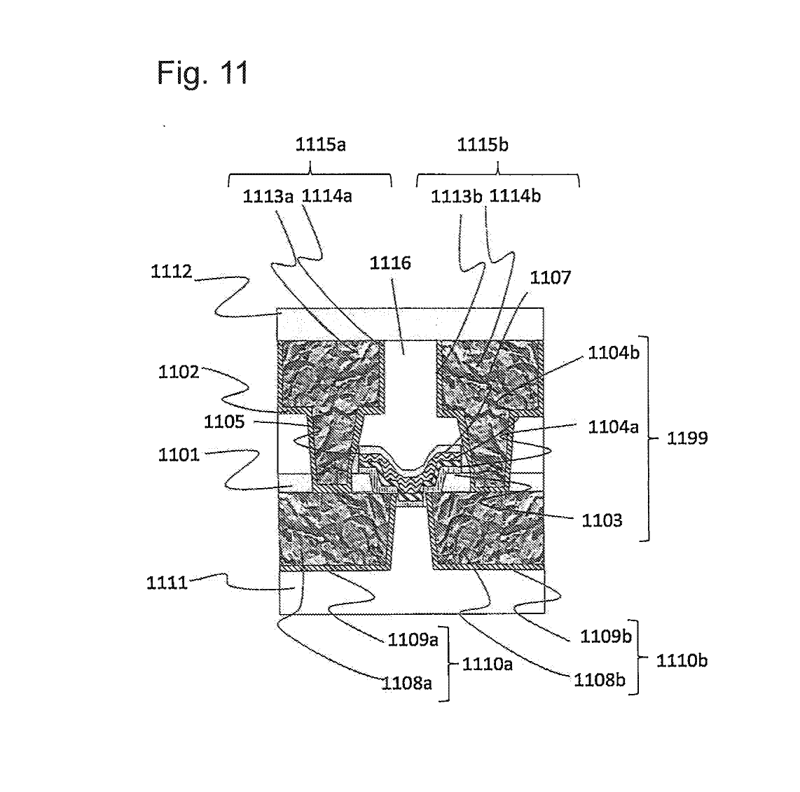

An example of a mode of the semiconductor device, in which the variable resistance element according to the third exemplary embodiment of the present invention is used as a non-volatile switching element provided in a multi-layered wiring layer, is described with reference to the drawings. FIG. 11 is a cross-sectional view schematically illustrating a fourth mode of the variable resistance element according to the third exemplary embodiment of the present invention, used as the non-volatile switching element provided in the multi-layered wiring layer of the semiconductor device.

The variable resistance element of the fourth mode illustrated in FIG. 11 is formed in a mode of a three-terminal solid electrolyte switch.

A variable resistance element 1199 illustrated in FIG. 11 uses each of two copper wirings including a copper wiring 1108a of a copper wiring layer (first copper wiring) 1110a in a lower layer and a copper wiring 1108b of a copper wiring layer (first copper wiring) 1110b in the lower layer, as the “first electrodes” that functions as the “ion supplying layers”. Thus, the three-terminal solid electrolyte switch is formed. A variable resistance film 1103 is formed of a solid electrolyte and functions as the “ion conducting layer”. A “first electrode” 1104, in contact with an upper surface of the variable resistance film 1103, has a stacked structure including a first upper electrode 1104a and a second upper electrode 1104b. The first upper electrode 1104a in the “first electrode” 1104 is in contact with the upper surface of the variable resistance film 1103. The upper surface of the “first electrode” 1104, that is, the upper surface of the second upper electrode 1104b is provided with an upper surface protection film 1107.

The variable resistance film 1103 and the “first electrode” 1104 of the variable resistance element 1199 are formed on the upper surface of a first interlayer insulation film 1101.

The variable resistance film 1103 is in contact with a surface of the copper wiring 1108a of the copper wiring layer (first copper wiring) 1110a in the lower layer and the copper wiring 908b of the copper wiring layer (first copper wiring) 1110b via a hole opened in the first interlayer insulation film 1101. Thus, in a portion of the opened hole, the lower surface of the variable resistance film 1103 is in contact with the “first electrode” that functions as the “ion supplying layer”, that is, the copper wiring 1108a of the copper wiring layer (first copper wiring) 1110a and the copper wiring 1108b of the copper wiring layer (first copper wiring) 1110b in the lower layer, and the upper surface of the variable resistance film 1103 is in contact with the first electrode 1104 that functions as the “second electrode”. Thus, the variable resistance element 1199 forms the three-terminal solid electrolyte switch having a configuration in which two “copper filament deposition variable resistance elements” are connected in parallel through the “second electrode”.

The side surfaces of the variable resistance film 1103, the first upper electrode 1104a, the second upper electrode 1104b, and the upper surface protection film 1107 are covered with a protective insulation film 1106. As a result, at least the side surfaces of the variable resistance film 1103, the first upper electrode 1104a, and the second upper electrode 1104b are covered with the protective insulation film 1106, and the upper surface of the second upper electrode 1104b is covered with the upper surface protection film 1107.

For example, as the solid electrolyte used for forming the variable resistance film 1103, an organic polymer film including SiO is preferably selected. The first upper electrode 1104a may be formed by using Ru, and the second upper electrode 1104b may be formed by using Ta or TaN.

The upper surface protection film 1107 and the protective insulation film 1105 are preferably formed of the same material. The protective insulation film 1105 and the upper surface protection film 1107 are formed of insulation film having functions of preventing the variable resistance film 1103, the first upper electrode 1104a, and the second upper electrode 1104b from being oxidized by oxygen when the second interlayer insulation film 1102 is formed and of preventing the entrance of water. When an oxide film having ion conductivity is used as the solid electrolyte, forming the variable resistance film 1103, the protective insulation film 1105 is an insulation film having a function of preventing desorption of oxygen from the solid electrolyte. The protective insulation film 1105 and the upper surface protection film 1107 are preferably formed by using a SiN film or the like, for example.

The copper wiring layer (first copper wiring) 1110a in the lower layer includes the copper wiring 1108a embedded via barrier metal 1109b in a first wiring trench formed in an interlayer insulation film 1111 in the lower layer. The copper wiring layer (first copper wiring) 1110b in the lower layer includes the copper wiring 1108b embedded via barrier metal 1109b in a second wiring trench formed in an interlayer insulation film 1111 in the lower layer. The first interlayer insulation film 1101 is formed on the upper surfaces of the copper wiring layer (first copper wiring) 1110a and the copper wiring layer (first copper wiring) 1110b in the lower layer. The first interlayer insulation film 1101 has a function as an insulating barrier film for preventing diffusion of copper from the upper surfaces of the copper wiring layer (first copper wiring) 1110a and the copper wiring layer (first copper wiring) 1110b in the lower layer. A SiCN film or the like is preferably used for forming the first interlayer insulation film 1101, to provide the function as the insulating barrier film.

The second interlayer insulation film 1102 is in direct contact with the first interlayer insulation film 1101. A third interlayer insulation film 1116 is formed above the second interlayer insulation film 1102. The third interlayer insulation film 1116 is in direct contact with the second interlayer insulation film 1102

A copper wiring layer (second copper wiring) 1115a in an upper layer and a copper wiring layer (second copper wiring) 1115b in the upper layer is formed in the third interlayer insulation film 1116. The copper wiring layer (second copper wiring) 1115a formed in the third interlayer insulation film 1116 is integrally formed with a contact plug portion that penetrates through the second interlayer insulation film 1102 and the first interlayer insulation film 1101 to reach a surface of the copper wiring layer (first copper wiring) 1110a in the lower layer. The copper wiring layer (second copper wiring) 1115b formed in the third interlayer insulation film 1116 is integrally formed with a contact plug portion that penetrates through the second interlayer insulation film 1102 and the first interlayer insulation film 1101 to reach a surface of the copper wiring layer (first copper wiring) 1110b in the lower layer. The copper wiring layer (second copper wiring) 1115a in the upper layer and the contact plug portion include a copper wiring 1114a embedded via barrier metal 1113a in a wiring trench formed in the third interlayer insulation film 1116 and a contact hole portion penetrating the second interlayer insulation film 1102 and the first interlayer insulation film 1101 to reach the surface of the copper wiring layer (first copper wiring) 1110a in the lower layer. The copper wiring layer (second copper wiring) 1115b in the upper layer and the contact plug portion include a copper wiring 1114b embedded via barrier metal 1113b in a wiring trench formed in the third interlayer insulation film 1116 and a contact hole portion penetrating the second interlayer insulation film 1102 and the first interlayer insulation film 1101 to reach the surface of the copper wiring layer (first copper wiring) 1110b in the lower layer.

The contact plug portion integrally formed with the copper wiring layer (second copper wiring) 1115a in the upper layer has a side wall partly in contact with the protective insulation film 1105. The contact plug portion integrally formed with the copper wiring layer (second copper wiring) 1115b in the upper layer also has a side wall partly in contact with the protective insulation film 1105.

The surface of the copper wiring layer (second copper wiring) 1115a in the upper layer and the surface of the copper wiring layer (second copper wiring) 1115b in the upper layer are covered with an insulating barrier film 1112 for preventing diffusion of copper from the copper wiring 1114a of the copper wiring layer (second copper wiring) 1115a in the upper layer and the copper wiring 1114b of the copper wiring layer (second copper wiring) 1115b in the upper layer. A SiCN film or the like is preferably used for forming the insulating barrier film 1112, as in the case of the first interlayer insulation film 1101.

The barrier metal 1109a for the copper wiring layer (first copper wiring) 1110a in the lower layer is a conductive film, having a barrier property, and covers the side and bottom surfaces of the copper wiring 1108a to prevent the copper, as the main component of the copper wiring 1108a of the copper wiring layer (first copper wiring) 1110a in the lower layer, from diffusing into the interlayer insulation film 1111 in the lower layer. The barrier metal 1109b for the copper wiring layer (first copper wiring) 1110b in the lower layer is a conductive film, having a barrier property, and covers the side and bottom surfaces of the copper wiring 1108b to prevent the copper, as the main component of the copper wiring 1108b of the copper wiring layer (first copper wiring) 1110b in the lower layer, from diffusing into the interlayer insulation film 1111 in the lower layer. Similarly, the barrier metal 1113a for the copper wiring layer (second copper wiring) 1115a in the upper layer is a conductive film, having a barrier property, and covers the side and bottom surfaces of the copper wiring 1114a to prevent the copper, as the main component of the copper wiring 1114a of the copper wiring layer (first copper wiring) 1115a in the upper layer, from diffusing into the third interlayer insulation film 1116, the second interlayer insulation film 1102, and the first interlayer insulation film 1101. The barrier metal 1113b for the copper wiring layer (second copper wiring) 1115b in the lower layer is a conductive film, having a barrier property, and covers the side and bottom surfaces of the copper wiring 1114b to prevent the copper, as the main component of the copper wiring 1114b of the copper wiring layer (first copper wiring) 1115b in the lower layer, from diffusing into the third interlayer insulation film 1116, the second interlayer insulation film 1102, and the first interlayer insulation film 1101.

As the conductive film having the barrier property against the diffusion of copper, for example, refractory metal or nitride of the same such as tantalum (Ta), tantalum nitride (TaN), titanium nitride (TiN), tungsten carbonitride (WCN), or a stacked film of these is used for the barrier metal 1109a for the copper wiring layer (first copper wiring) 1110a in the lower layer, the barrier metal 1109b for the copper wiring layer (first copper wiring) 1110b in the lower layer, the barrier metal 1113a for the copper wiring layer (second copper wiring) 1115a in the upper layer, and the barrier metal 1113b for the copper wiring layer (second copper wiring) 1115b in the upper layer.

Also in the variable resistance element of the fourth mode illustrated in FIG. 11, the second interlayer insulation film 1102 and the third interlayer insulation film 1116 are formed of different insulating materials. The third interlayer insulation film 1116 and the insulating barrier film 1112 are formed of different insulating materials. Similarly, the interlayer insulation film 1111 in the lower layer and the first interlayer insulation film 1101 that functions as the insulating barrier film are formed of different insulating materials. The first interlayer insulation film 1101 and the second interlayer insulation film 1102 are formed of different insulating materials.

As described above, a SiCN film or the like is preferably used for forming the first interlayer insulation film 1101 that functions as the insulating barrier film and the insulating barrier film 1112.

In this case, the interlayer insulation film 1111 in the lower layer may be formed by using a SiO₂ film, a SiOC film, a SiOCH film, a low dielectric constant film, and the like.

A SiN film that used for manufacturing the protective insulation film 1105 and the upper surface protection film 1107 for example, have no oxygen permeability or water permeability, and thus protects the variable resistance film 1103, the first upper electrode 1104a, and the second upper electrode 1104b, in the process of forming the second interlayer insulation film 1102.

In this case, an insulating material with a smaller relative-dielectric constant than the SiN film and the SiCN film used for manufacturing the first interlayer insulation film 1101, the protective insulation film 1105, and the upper surface protection film 1107 for example, is preferably selected as an insulating material used for forming the second interlayer insulation film 1102. An insulating material with a smaller relative-dielectric constant than the insulating material, used for manufacturing the second interlayer insulation film 1102 is preferably selected as an insulating material used for forming the third interlayer insulation film 1116.

Thus, the relative dielectric constants are preferably set to satisfy the following condition: “the insulating material used for forming the first interlayer insulation film 1101”>the insulating material used for forming the second interlayer insulation film 1102”>“the insulating material used for forming the third interlayer insulation film 1116”.

When a SiN film or a SiCN film for example is selected as an insulating material with a high relative-dielectric constant (k=7) as “the insulating material used for forming the first interlayer insulation film 1101”,

a SiO₂ film for example, as an insulating material with a medium relative-dielectric constant of about (k=3.5 to 4.5) is preferably selected as “the insulating material used for forming the second interlayer insulation film 1102”, and

a SiOCH film for example, as an insulating material with a low relative-dielectric constant of about (k=2.5 to 3.5) is preferably selected as “the insulating material used for forming the third interlayer insulation film 1116”.

Through the selections described above, “the insulating material used for forming the second interlayer insulation film 1102” further provides an effect of lowering hygroscopicity.

The “insulating material used for manufacturing the protective insulation film 1105 and the upper surface protection film 1107” is preferably a film finer than “the insulating material used for forming the first interlayer insulation film 1101”, so that overwhelming “protection” characteristics can be achieved. To satisfy this condition, the insulating materials are selected in such a manner that the relative dielectric constant of the “insulating material used for manufacturing the protective insulation film 1105 and the upper surface protection film 1107” exceeds the relative dielectric constant of the “insulating material used for forming the first interlayer insulation film 1101”. For example, a SiN film is preferably used as the “insulating material used for manufacturing the protective insulation film 1105 and the upper surface protection film 1107”, and a SiCN film is preferably used as the “insulating material used for forming the first interlayer insulation film 1101”.

As illustrated in FIG. 11, in a hole area formed in the first interlayer insulation film 1101, the copper wiring layer (first copper wiring) 1110a and the copper wiring layer (first copper wiring) 1110b in the lower layer, as well as the interlayer insulation film 1111 in the lower layer are exposed. In a process of forming the hole in the first interlayer insulation film 1101, the interlayer insulation film 1111 in the lower layer is partially etched to be removed, and thus a recess is formed. The variable resistance film 1103 is formed to bury the recess.

The variable resistance film 1103 formed in the recess is in contact with the barrier metal 1109a for the copper wiring layer (first copper wiring) 1110a in the lower layer or the barrier metal 1109b for the copper wiring layer (first copper wiring) 1110b in the lower layer. Here, a configuration, in which the variable resistance film 1103 is sandwiched by the first electrode 1104 that functions as the “second electrode” and the barrier metal 1109a of the copper wiring layer (first copper wiring) 1110a in the lower layer or the barrier metal 1109b of the copper wiring layer (first copper wiring) 1110b in the lower layer, does not function as a metal filament precipitating variable resistance element.

Thus, a configuration, in which the variable resistance film 1103 is sandwiched by the first electrode 1104 that functions as the “second electrode” and the copper wiring 1108a of the copper wiring layer (first copper wiring) 1110a in the lower layer and a configuration, in which the variable resistance film 1103 is sandwiched by the first electrode 1104 that functions as the “second electrode” and the copper wiring 1108b of the copper wiring layer (first copper wiring) 1110b in the lower layer each only function independently as a “copper filament precipitating variable resistance element”. As exemplarily illustrated in FIG. 11, an area Sa of the portion where the variable resistance film 1103 is sandwiched by the first electrode 1104 that functions as the “second electrode” and the copper wiring 1108a of the copper wiring layer (first copper wiring) 1110a in the lower layer and an area Sb of the portion where the variable resistance film 1103 is sandwiched by the first electrode 1104 that functions as the “second electrode” and the copper wiring 1108b of the copper wiring layer (first copper wiring) 1110b in the lower layer may each independently be set. In other words, a resistance value of the “copper filament precipitating variable resistance element”, including the portion where the variable resistance film 1103 is sandwiched by the first electrode 1104 that functions as the “second electrode” and the copper wiring 1108a of the copper wiring layer (first copper wiring) 1110a in the lower layer, in the “ON” state and a resistance value of the “copper filament precipitating variable resistance element”, including the portion where the variable resistance film 1103 is sandwiched by the first electrode 1104 that functions as the “second electrode” and the copper wiring 1108b of the copper wiring layer (first copper wiring) 1110b in the lower layer, in the “ON” state may each independently be set.

The copper wiring layer (first copper wiring) 1110a in the lower layer and the copper wiring layer (first copper wiring) 1110b in the lower layer are electrically separated from each other, and thus can be independently provided with a voltage.

The copper wiring layer (first copper wiring) 1110a in the lower layer is connected to the copper wiring layer (first copper wiring) 1115a in the upper layer via the contact plug. The copper wiring layer (first copper wiring) 1110b in the lower layer is connected to the copper wiring layer (first copper wiring) 1115b in the upper layer via the contact plug.

Here, the side wall of the contact plug is in contact with the protective insulation film 1105 but is electrically insulated from the first upper electrode 1104a and the second upper electrode 1104b. Thus, the contact plug can be disposed at a position adjacent to the variable resistance element 1199. Thus, in the variable resistance element 1199 of the fourth mode, the copper wiring layer (first copper wiring) 1115a and the copper wiring layer (first copper wiring) 1115b that are in the upper layer can be disposed in higher density. The copper wiring layer (first copper wiring) 1115a and the copper wiring layer (first copper wiring) 1115b independently supply a voltage to the corresponding one of the copper wiring layer (first copper wiring) 1110a and the copper wiring layer (first copper wiring) 1110b that are in the lower layer.

All things considered, the variable resistance element 1199 of the fourth mode illustrated in FIG. 11 is the three-terminal solid electrolyte switch having the configuration in which the two “copper filament precipitating variable resistance elements” are connected in parallel through the “second electrode”. In this configuration, the two “copper filament precipitating variable resistance elements” may each independently be switched.

During the process of forming a contact hole portion passing through the second interlayer insulation film 1102 and the first interlayer insulation film 1101 and reaching the surface of the copper wiring layer (first copper wiring) 1110a in the lower layer and the process of forming a contact hole portion passing through the second interlayer insulation film 1102 and the first interlayer insulation film 1101 and reaching the surface of the copper wiring layer (first copper wiring) 1110b in the lower layer, in order to advance the etching of the second interlayer insulation film 1102 and the etching of the first interlayer insulation film 1101, a SiCN film is selected as the “insulating material used for forming the first interlayer insulation film 1101”, a SiO₂ film is selected as the “insulating material used for forming the second interlayer insulation film 1102”, and a SiN film is selected as the “insulating material used for forming the protective insulation film 1105 and the upper surface protection film 1107”, a high etching selectivity can be achieved. As a result, reduction in the film thicknesses of the protective insulation film 1105 and the upper surface protection film 1107 due to side etching can be prevented during the process of forming the contact hole portions.

(Fifth Mode)

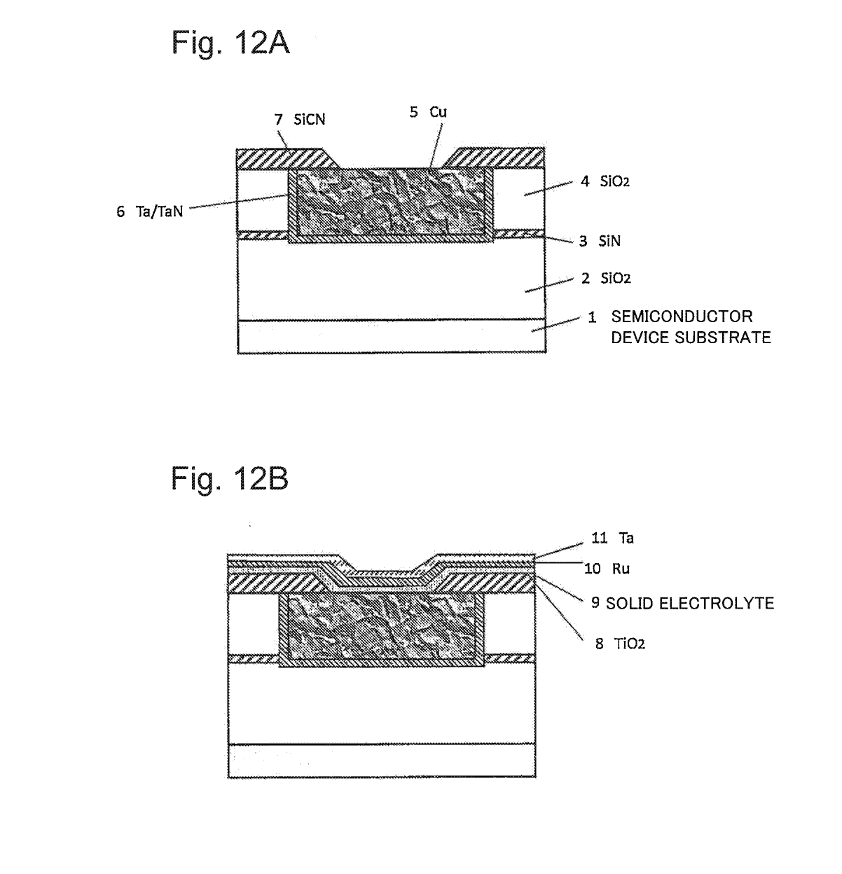

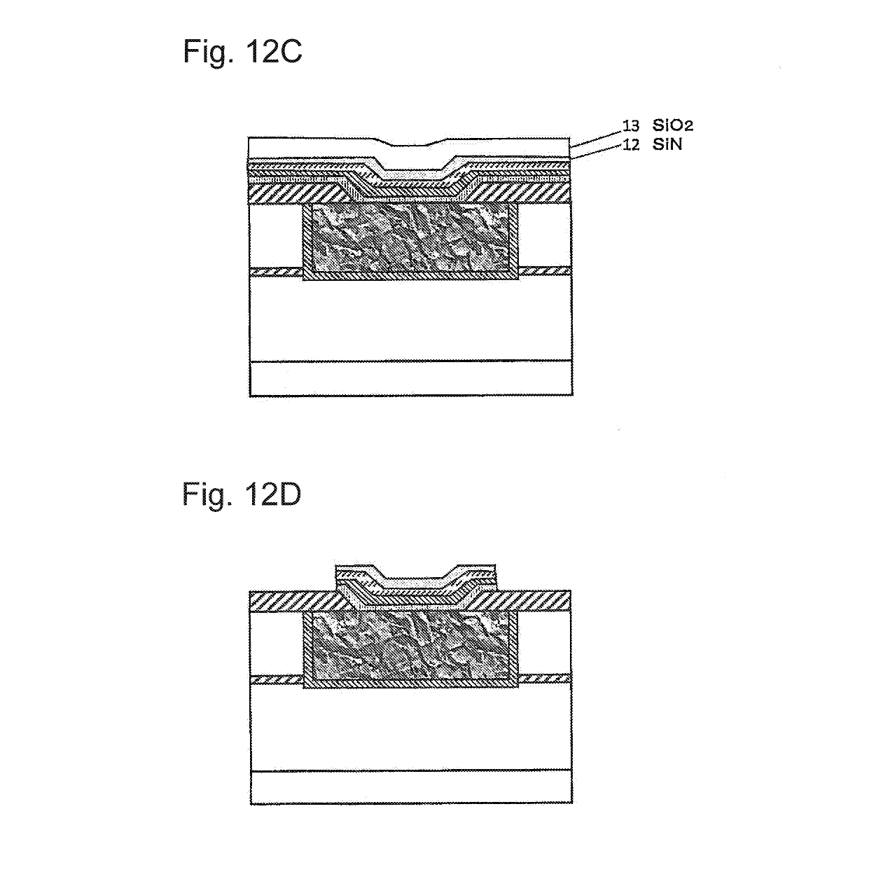

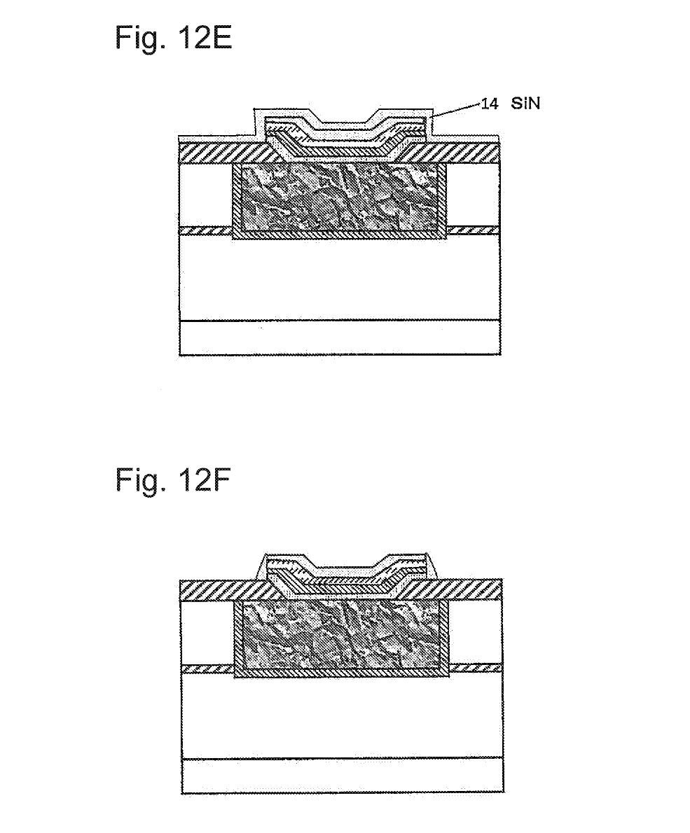

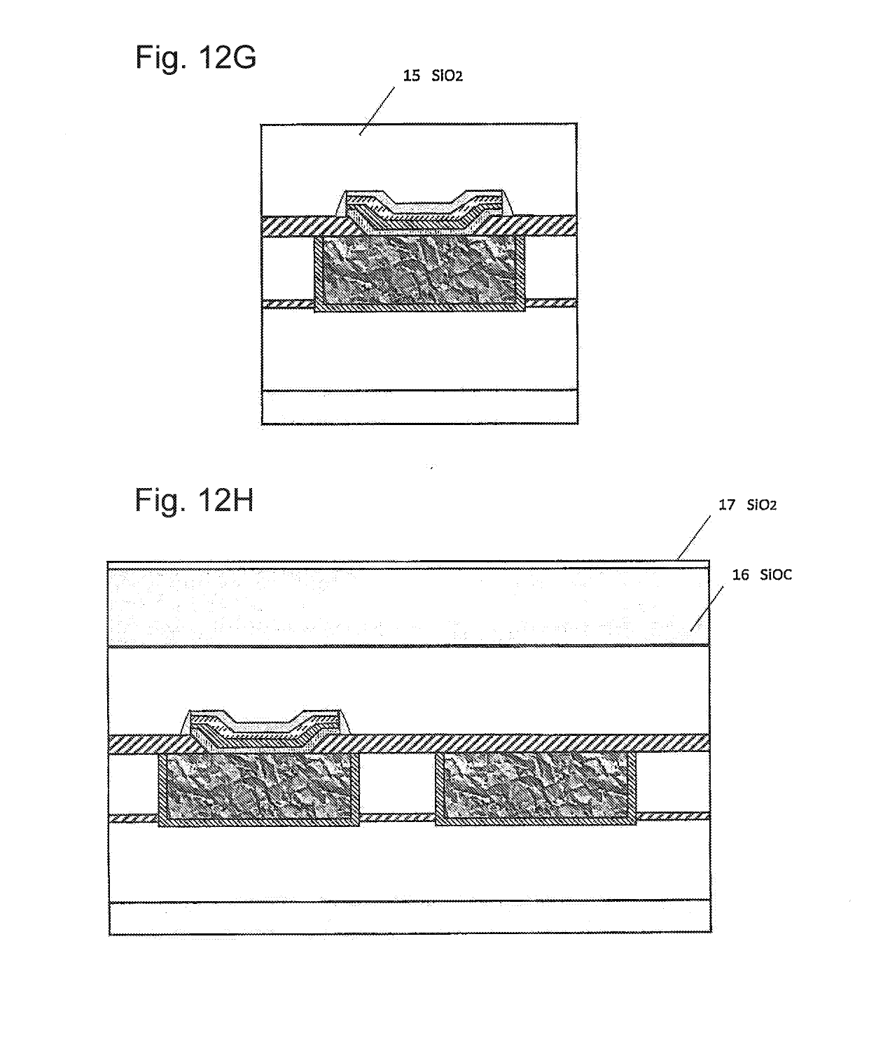

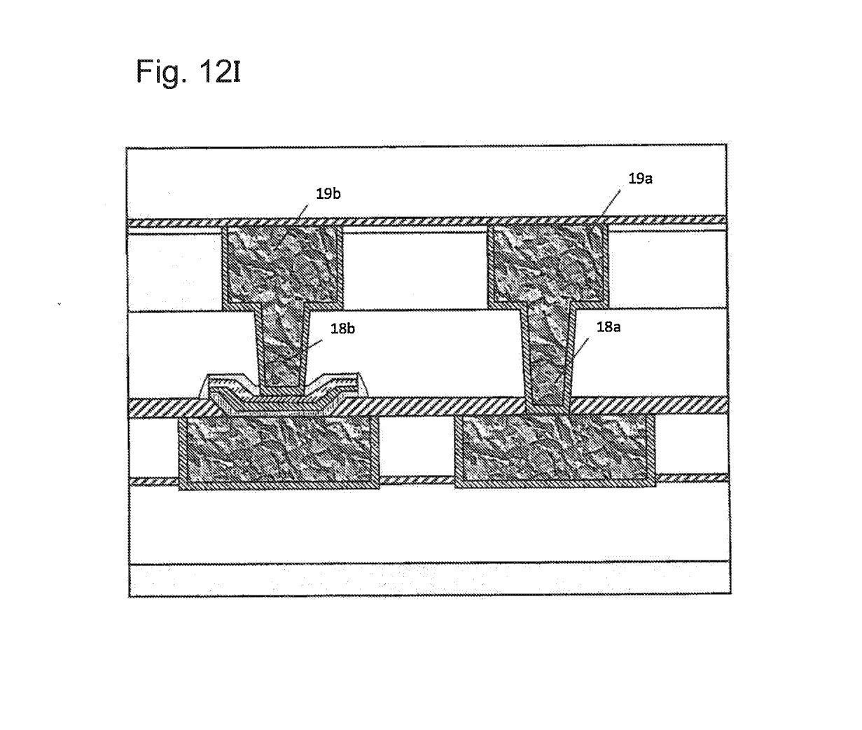

An example of a mode of the variable resistance element according to the third exemplary embodiment of the present invention used as the non-volatile switching element provided in the multi-layered wiring layer of the semiconductor device, and a process for producing the same are described with reference to the drawings. FIG. 12A to FIG. 12I are cross-sectional views schematically illustrating a fifth mode of the variable resistance element according to the third exemplary embodiment of the present invention, used as the non-volatile switching element provided in the multi-layered wiring layer of the semiconductor device, and a process for producing the same.

The variable resistance element of the fifth mode, of which the forming process is illustrated in FIG. 12A to FIG. 12I, is formed in a mode of a two-terminal solid electrolyte switch. In the producing process illustrated in FIGS. 12A to 12I, a semiconductor element (not illustrated), as a component of a semiconductor device itself, is formed on a surface of the semiconductor substrate before the multi-layered wiring layer is formed.

Step B1 to step B9 in the process for producing a semiconductor device substrate 1 having the semiconductor element formed on its surface, a multi-layered wiring layer and the variable resistance element of the fifth mode used as a non-volatile switching element in the multi-layered wiring layer are described with reference to FIG. 12A to FIG. 12I.

(Step B1)

As illustrated in FIG. 12A, step B1 is a step of forming the “first wiring” corresponding to the wiring layer in the lower layer and forming an opening in the insulating barrier film 7 that covers the surface of the “first wiring” used as the “first electrode” that functions as the “ion supplying layer”, when the variable resistance element is formed.

First of all, an interlayer insulation film 2, a barrier insulation film 3, and an interlayer insulation film 4 are formed in this order on the semiconductor device substrate 1. For example, a silicon oxide film having a film thickness of 300 nm is selected as the “insulating material used for forming the interlayer insulation film 2”, a SiN film having a film thickness of 50 nm is selected as the “insulating material used for forming the barrier insulation film 3”, and a SiO₂ film having a film thickness of 200 nm is selected as the “insulating material used for forming the interlayer insulation film 4”.

Then, a wiring trench for producing the “first wiring” is formed in the interlayer insulation film 4, the barrier insulation film 3, and the interlayer insulation film 2. The step of forming the wiring trench includes:

a resist mask forming processing step of forming a resist mask having openings in a predetermines pattern on the interlayer insulation film 4 by photolithography;

an etching processing step of performing anisotropic etching through dry etching on stacked films by using the resist mask as an etching mask layer; and

a resist mask removing processing step of removing the resist mask after the wiring trench is formed by the anisotropic etching.

Then, metal 5 is embedded in the wiring trench with barrier metal 6 provided in between, whereby the “first wiring” is formed. The metal 5 of the “first wiring” is used as the “ion supplying layer”. Thus, a metal material mainly composed of copper, for example, copper, is used. The barrier metal 6 prevents the diffusion of copper used for the metal 5. Thus, for example, a stacked structure of TaN (film thickness of 5 nm)/Ta (film thickness of 5 nm) is used as the barrier metal 6.

The barrier metal 6, formed of the stacked structure of TaN (film thickness of 5 nm)/Ta (film thickness of 5 nm), is formed to cover bottom and side wall portions of the wiring trench in a uniform thickness. Thus, a deposition film, having the stacked structure, is formed on upper surface of the interlayer insulation film 4 and on the bottom and side wall portions of the wiring trench by isotropic deposition method such as RF sputtering for example. The copper, used for the metal 5, uses the barrier metal 6 as a base layer, and is formed to be buried in the wiring trench by plating for example. Then, the stacked structure TaN (film thickness of 5 nm)/Ta (film thickness of 5 nm) formed on the upper surface of the interlayer insulation film 4 is removed by CMP (Chemical-Mechanical Polishing) for example, whereby the upper surface of the “first wiring” formed in the wiring trench is planarized.

Then, the insulating barrier film 7 covering the upper surfaces of the “first wiring” and the interlayer insulation film 4 is formed. The insulating barrier film 7 prevents the diffusion of copper used for the metal 5 of the “first wiring”. Thus, a SiCN film having a film thickness of 30 nm is selected as the “insulating material used for forming the insulating barrier film 7” for example.

An opening is formed at a portion of the insulating barrier film 7 covering the surface of the metal 5 of the “first wiring” as part, of the “first wiring” corresponding to the wiring layer in the lower layer, functioning as the “ion supplying layer” when the variable resistance element is produced.

The opening is not formed for the insulating barrier film 7 covering the surface of the other part of the “first wiring” not used for forming the variable resistance element. Thus, at the point when step B1 where completed, the “first wiring” corresponding to the wiring layer in the lower layer is covered with the insulating barrier film 7, except for the part of the “first wiring” used for forming the variable resistance element.

In the step of forming the opening in the insulating barrier film 7, covering the surface of the metal 5 of the “first wiring”, the resist mask having the openings is used so that the isotropic etching is performed on the insulating barrier film 7 exposed from the openings of the resist mask, through dry etching such as reactive dry etching for example.

In the step of performing the isotropic etching on the SiCN film used as the insulating barrier film 7, that following conditions may be employed as the conditions for the reactive dry etching: CF₄/Ar gas flow rate=25:50 sccm, pressure of 0.53 [Pa], source power of 400 W, and substrate bias power of 90 W

Through the reactive dry etching, etching proceeds on a side wall surface of the opening formed in the SiCN film. Thus, side etching proceeds around the opening of the resist mask, that is, on an upper portion of the SiCN film covered with the resist mask, whereby the opening thus formed has a tapered shaped side wall surface. Here, with a condition with lower source power and higher substrate bias power, a “taper angle” of the side wall surface of the “tapered shape” can be reduced with improved “ionic character” in the etching contributing to the “reactive ion etching” process.

The “taper angle” of the side wall surface of the “tapered shape” is reduced by utilizing the side etching on the side wall surface of the formed opening. Thus, etching time for etching the SiCN film having the film thickness 30 nm can be set to the time in which the SiCN film can be etched by 35 nm. Specifically, the etching time is set to the time in which “over etching” proceeds so as to increase the side etching amount in the upper portion of the SiCN film, whereby the “taper angle” of the “tapered shaped” side wall surface can be reduced.

The “over etching processing” for reducing the “taper angle” of the “tapered shaped” side wall surface can be performed by an “etching back” process.

For example, “etch back” can be performed on the SiCN film exposed from the side wall surface of the formed opening by using an “etch back” function provided to a sputtering apparatus by heating the substrate to 350° C. under reduced-pressure atmosphere. More specifically, in a heat chamber in the sputtering apparatus, the heating processing can be performed under reduced-pressure atmosphere to performed the “etch back” as desired.

The “etch back” can be performed on the SiCN film exposed from the side wall surface of the opening by using RF etching using unreactive gas. Specifically, the RF etching using the unreactive gas can be performed in the RF etching chamber by using Ar gas as the unreactive gas and under the conditions of Ar gas flow rate=30 sccm, pressure of 1.3 [Pa], source power of 290 W, and substrate bias power of 130 W. Here, the RF etching time is set to be time in which the SiO₂ film formed by plasma-enhanced CVD can be etched by 2 nm through the RF etching, whereby the desired “etch back” of the SiO₂ film can be achieved.

With the “tapered shaped” side wall surface of the opening formed in the SiCN film having a small “taper angle”, “step coverage” on the side wall surface of the opening can be improved when the stacked structure including a metal Ti film, the solid electrolyte film 9, the first upper electrode 10, and the second upper electrode 11 is formed in the opening in the subsequent step B2.

(Step B2)

Step B2 is a step of sequentially forming a titanium oxide film 8, the solid electrolyte film 9, the first upper electrode 10, and the second upper electrode 11 on the upper surface of the insulating barrier film 7 and in the formed opening as illustrated in FIG. 12B for forming the variable resistance element. The titanium oxide film 8 prevents oxidation of the surface of the metal (copper wiring) 5 of the “first wiring”. The solid electrolyte film 9 is used as the “ion conductive layer”. The first upper electrode 10 and the second upper electrode 11 form the first electrode that functions as the “second electrode”.

The metal Ti film having a film thickness of 1 nm is deposited on the surface of the metal (copper wiring) 5 of the “first wiring” exposed from the opening formed in the insulating barrier film 7, the “tapered shaped” side wall surface of the opening, and the upper surface of the insulating barrier film 7 by DC sputtering. The metal Ti film functions as “oxidation sacrificing layer” for preventing the surface of the metal (copper wiring) 5 of the “first wiring” from oxidizing in the step of forming the solid electrolyte film 9.

In the variable resistance element of the fifth mode, the solid electrolyte film 9 used as the “ion conducting layer” is formed by using a “porous polymer film” formed of a porous polymer mainly composed of silicon, oxygen, and carbon. The “porous polymer film” formed of the porous polymer mainly composed of silicon, oxygen, and carbon is, for example, deposited with a cyclic siloxane organic polymer disclosed in WO 2011/058947 and by “polymerization reaction” of the organic polymer in a RF plasma process. In the process of the “polymerization reaction” of the organic polymer, oxygen plasma is generated by organic monomer decomposition. The metal Ti film is converted into the titanium oxide film 8 through ad effect of the oxygen plasma thus generated.

As a result, the porous polymer film” formed of the porous polymer mainly composed of silicon, oxygen, and carbon is deposited on the titanium oxide film 8 converted from the metal Ti film. In the step of depositing the “porous polymer film” by the RF plasma-enhanced CVD, the deposition condition can be selected in the range of RF power 50 to 300 W, the temperature of 350° C., mixture gas including He, the pressure 1.0 to 6.0 [Torr].

When the variable resistance element of the fifth mode is formed, specifically, when a 12-inch plasma CVD reactor is used, the “porous polymer film” can be formed by selecting the conditions of He gas flow rate=500 sccm, the pressure of 400 [Pa], and the RF power of 80 W. The “porous polymer film” having the film thickness of 5 nm is formed by employing the depositing conditions and using the cyclic siloxane organic polymer as a raw material, to be used for forming the solid electrolyte film 9.

The “porous polymer film” having a film thickness of 5 nm was actually deposited employing the depositing conditions and using the cyclic siloxane organic polymer as a raw material, and then a cross section is observed by TEM (Transmission Electron Microscope). Thus, the titanium oxide film having the film thickness of 2.0 nm was found to be formed by the metal Ti film having the film thickness of 1 nm. The density of the metal Ti is 4.506 g/cm³, whereas the density of crystalline titanium oxide (IV) such as for example, TiO₂ of an anatase structure is 3.84 g/cm³, and TiO₂ of a rutile structure is 4.26 g/cm³. Thus, the titanium oxide film having the film thickness of 2.0 nm, formed from the metal Ti film having the film thickness 1 nm, is expected to be an anatase titanium oxide (IV) film.

Depending on the device configuration of the RF plasma-enhanced CVD apparatus and the deposition conditions to be used, the oxidizing power of the oxygen plasma might overwhelm the oxidizing power under the deposition conditions described above. In such a case, the film thickness of the metal Ti film is increased to prevent the oxidation of the surface of the metal (copper) 5 of the “first wiring”.

With the depositing conditions for reducing the generated oxygen plasma, such as lower RF power and increased raw material flow rate, the oxygen generated by the raw material organic monomer decomposition is reduced. In such a case, the surface of the metal (copper) 5 of the “first wiring” can be prevented from being oxidized even when the metal Ti film that functions as the “oxidation sacrificing layer” has a small film thickness.

When the depositing conditions sufficiently reducing the generated oxygen plasma can be selected, the oxidation of the surface of the metal (copper) 5 of the “first wiring” does not substantially proceeds in the step of depositing the “porous polymer film” even when the deposition of the metal Ti film is omitted. Thus, by covering the surface of the metal (copper) 5 of the “first wiring” with a thin “porous polymer film” while the oxidation of the surface of the metal (copper) 5 of the “first wiring” is not substantially proceeding, the oxygen plasma cannot act on the surface of the metal (copper) 5 of the “first wiring”. As a result, the oxidation of the surface of the metal (copper) 5 of the “first wiring” does not substantially proceeds in the step of depositing the “porous polymer film” even when the deposition of the metal Ti film is omitted.

After the step of depositing the “porous polymer film” has been completed and the titanium oxide film 9 and the solid electrolyte film 9 have been formed, the first upper electrode 10 and the second upper electrode 11 are formed on the solid electrolyte film 9 in this order. The first upper electrode 10, in contact with the upper surface of the solid electrolyte film 9, functions as the “second electrode”. For example, a Ru film having a film thickness of 10 nm is used for forming the first upper electrode 10. The second upper electrode 11 covers the upper surface of the first upper electrode 10, and functions as an “etching stop layer” in an etching step for forming a hole in the SiN film used for forming the upper surface protection film 12 in a step of forming a via hole described later. Thus, for example, a Ta film having a film thickness of 25 nm is used for forming the second upper electrode 11.

When the “porous polymer film” that is formed of a porous polymer mainly composed of silicon, oxygen, and carbon and used as the solid electrolyte film 9 is kept at a low pressure and a high temperature, desorption of contained oxygen might occur. When a reaction occurs between the desorbed oxygen and Ru used for forking the first upper electrode 10, a “RuO₂” boundary coat layer is formed on the boundary between the first upper electrode 10 and the solid electrolyte film 9.

When the “RuO₂” boundary coat layer is formed on the boundary between the first upper electrode 10, used as the “second electrode” of the copper filament deposition variable resistance element, and the solid electrolyte film 9, functioning as the “ion conducting layer”, “copper atom deposition” is prevented. Thus, the oxygen desorption of the “porous polymer film” that is formed of a porous polymer mainly composed of silicon, oxygen, and carbon and used as the solid electrolyte film 9 is not caused. A Ru film having a film thickness of 10 nm is deposited by selecting the deposition condition. For example, the Ru film is deposited at a room temperature by DC sputtering with Ru as a target under the conditions of DC power of 0.2 kW, Ar gas, and pressure of 0.27 [Pa]. A Ta film, used for forming the second upper electrode 11, is also deposited at a room temperature by DC sputtering with Ta as a target under the conditions of DC power of 0.2 kW, Ar gas, and pressure of 0.27 [Pa].

An isotropic sputtering process is employed in each of the steps for forming the titanium oxide film 8 having a film thickness of 2.0 nm, the solid electrolyte film 9 having a film thickness of 5 nm, the first upper electrode 10 having a film thickness of 10 nm, and the second upper electrode 11 having a film thickness of 25 nm. Thus, as illustrated in FIG. 12B, the stacked structure having a total film thickness 42 nm is uniformly formed to cover the bottom surface of the opening formed in the insulating barrier film 7 having a film thickness of 30 nm, the “tapered shaped” side wall surface of the opening, and the upper surface of the insulating barrier film 7.

(Step B3)

Step B3 includes a step of depositing a SiN film used for forming the upper surface protection film 12 disposed on the upper surface of the second upper electrode 11 of the first upper electrode 10 and the second upper electrode 11 forming the first electrode that functions as the “second electrode” for forming the variable resistance element and a step of depositing a SiO₂ film (hard mask film) 13 used as a hard mask in a step of patterning the titanium oxide film 8, the solid electrolyte film 9, the first upper electrode 10, the second upper electrode 11, and the upper surface protection film 12 for forming the variable resistance element as illustrated in FIG. 12C.

The SiN film that has a film thickness of 30 nm and is used for forming the upper surface protection film 12, is deposited on the upper surface of the Ta film used for forming the second upper electrode 11. Then, the SiO₂ film (hard mask film) 13 that has a film thickness of 200 nm and is used as a hard mask in the pattering step is deposited.

The SiN film that has a film thickness of 30 nm and is used for forming the upper surface protection film 12 can be deposited by plasma-enhanced CVD with SiH₄ and N₂ as raw material gas. Here, a film forming temperature in the plasma-enhanced CVD can be selected in the range of 200° C. to 400° C. Still, the SiN film is formed by using high density plasma with the temperature selected as 200° C. Bu selecting the deposition condition, the isotropic deposition is achieved, whereby a substantially uniform film thickness of the SiN film deposited on the bottom surface of the opening, the “tapered shaped” side wall surface of the opening, and on the insulating barrier film 7 is achieved.

The SiO₂ film (hard mask film) 13 that has a film thickness of 200 nm and is used as a hard mask is also deposited by the plasma-enhanced CVD. A growth temperature is selected to be 200° C., and the film thickness of the deposition is 200 nm, which is much larger than a height difference of 30 nm between a bottom surface area of the opening and an upper area of the insulating barrier film 7, and thus as illustrated in FIG. 12C, the height difference is offset and the film thickness at the bottom surface area is thicker than the film thickness at the upper area of the insulating barrier film 7.

(Step B4)

Step B4 includes a step of performing patterning by sequentially selectively etching the upper surface protection film 12, the second upper electrode 11, the first upper electrode 10, the solid electrolyte film 9, and the titanium oxide film 8, by using the hard mask formed of the SiO₂ film (hard mask film) 13, and a subsequent step of selectively etching ad thus removing the hard mask formed of the SiO₂ film (hard mask film) 13. When the patterning of the upper surface protection film 12, the second upper electrode 11, the first upper electrode 10, the solid electrolyte film 9, and the titanium oxide film 8 is completed in the end, the stacked structure illustrated in FIG. 12D is formed in an opening area where the variable resistance element is formed.

A photoresist mask (not illustrated) corresponding to the patterning shape of the variable resistance element portion is formed on the hard mask formed of the SiO₂ film (hard mask film) 13. The dry etching is performed on the SiO₂ film (hard mask film) 13 by using the photoresist mask, until the surface of the SiN film used for forming the upper surface protection film 12 appears. Then, processing of oxygen plasma ashing and organic stripping is performed to remove the photoresist mask. The SiO₂ film (hard mask film) 13, patterned to match the patterning shape of the variable resistance element portion, is used as the hard mask in the later patterning step.

In a step of performing dry etching of the SiO₂ film (hard mask film) 13, dry etching without the side etching proceeding, that is, anisotropic dry etching is employed. For example, in the step of dry-etching the SiO₂ film (hard mask film) 13, a general parallel-plate dry etching apparatus can be used. Here, conditions providing selectivity for the SiN film used for forming the upper surface protection film 12 are selected as the dry etching condition for the SiO₂ film (hard mask film) 13. For example, the dry etching on the SiO₂ film (hard mask film) 13 is performed under the conditions of CF₄ gas flow rate=140 sccm, a pressure of 6.6 [Pa], source power of 1200 W, and substrate bias power of 700 W. Preferably, the etching is stopped on the upper surface of the SiN film having a film thickness of 30 nm, at the point where the dry etching on the SiO₂ film (hard mask film) 13 having a film thickness of 200 nm is completed. To prevent the SiO₂ film (hard mask film) 13 from remaining, etching time in which the SiN film having a film thickness of 30 nm is partially etched can be selected.

The second upper electrode 11, the first upper electrode 10, and the ion conducting film 9 have the upper surfaces covered with the SiN film 12, and thus are not exposed to the oxygen plasma in the oxygen plasma ashing for removing the photoresist mask.

After the photoresist mask is removed, patterning is performed by sequentially selectively etching the upper surface protection film 12, the second upper electrode 11, the first upper electrode 10, the solid electrolyte film 9, and the titanium oxide film 8 by using the patterned SiO₂ film (hard mask film) 13.

Also in the step of dry etching the SiN film having a film thickness of 30 nm, used for forming the upper surface protection film 12, the dry etching without the side etching proceeding, that is, anisotropic dry etching is employed. Etching conditions providing selectivity to the metal Ta film having a film thickness of 25 nm, used for forming the second upper electrode 11, are selected. For example, the dry etching for the SiN film 12 can be performed by using the parallel-plate dry etching apparatus, and under the conditions of CF₄/Ar gas flow rate=25/50 sccm, pressure of 0.53 [Pa], source power of 400 W, and substrate bias power of 90 W.

Also in the step of dry etching the metal Ta film having a film thickness of 25 nm, used for forming the second upper electrode 11, the dry etching without the side etching proceeding, that is, anisotropic dry etching is employed. Etching conditions providing selectivity to the metal Ru film having a film thickness of 10 nm, used for forming the first upper electrode 10, are selected. For example, the dry etching for the metal Ta film having a film thickness of 25 nm can be performed by using the parallel-plate dry etching apparatus, and under the conditions of Cl₂ gas flow rate=50 sccm, pressure of 0.53 [Pa], source power of 400 W, and substrate bias power of 60 W.

Also in the step of dry etching the metal Ru film having a film thickness of 10 nm, used for forming the first upper electrode 10, the dry etching without the side etching proceeding, that is, anisotropic dry etching is employed. Etching conditions providing selectivity to the “porous polymer film” having a film thickness of 5 nm, used for forming the solid electrolyte film 9, are selected. For example, the dry etching for the metal Ru film having a film thickness of 10 nm can be performed by using the parallel-plate dry etching apparatus, and under the conditions of Cl₂/O₂ gas flow rate=5/40 sccm, pressure of 0.53 [Pa], source power of 900 W, and substrate bias power of 100 W.

Also in the step of dry etching the “porous polymer film” having a film thickness of 5 nm, used for forming the solid electrolyte film 9, and dry etching the titanium oxide film 8 having a film thickness of 2.0 nm, the dry etching without the side etching proceeding, that is, anisotropic dry etching is employed. Etching conditions providing selectivity to the SiCN film having a film thickness of 30 nm, used for forming the insulating barrier film 7 in the lower layer, are selected. The dry etching for the “porous polymer film” having a film thickness of 5 nm can be performed by using the parallel-plate dry etching apparatus, and under the conditions of Cl₂/CF₄/Ar gas flow rate=45/15/15 sccm, pressure of 1.3 [Pa], source power of 800 W, and substrate bias power of 60 W. The dry etching for the titanium oxide film 8 having a film thickness of 2.0 nm can be performed under the conditions of Cl₂/O₂ gas flow rate=20/160 sccm, pressure of 0.5 [Pa], source power of 600 W, and substrate bias power of 160 W. Chloride gas (Cl₂) is intentionally used to achieve higher selectivity of the SiCN film having a film thickness of 30 nm, used for forming the insulating barrier film 7 in the lower layer, whereby generation of a sub trench and the like is prevented. The “porous polymer film” having a film thickness of 5 nm and the titanium oxide film 8 having a film thickness of 2.0 nm do not remain on the upper surface of the insulating barrier film 7, excluding an area where the variable resistance element is formed, at the point where the patterning of the solid electrolyte film 9 and the titanium oxide film 8, forming the “ion conducting layer” is completed.

After the series of patterning steps described above have been completed, the patterned SiO₂ film (hard mask film) 13, used as the hard mask, is selectively etched to be removed. The film thickness of the patterned SiO₂ film (hard mask film) 13 is slightly larger at an area where the variable resistance element is formed, especially, at the center area of the opening, than other peripheral area. The SiO₂ film (hard mask film) 13 is selectively etched under conditions providing a high selectivity to the SiCN film used for forming the insulating barrier film 7 that is exposed.

Here, while the SiCN film used for forming the insulating barrier film 7 may be slightly etched in an area where the upper surface of the insulating barrier film 7 is exposed, the conditions of selectively etching the SiO₂ film (hard mask film) 13 are selected so that the film thickness of the exposed SiCN film fall in the range of 20 to 30 nm.

The film thickness of the patterned SiO₂ film (hard mask film) 13 is slightly larger at an area where the variable resistance element is formed, especially, at the center area of the opening, than the peripheral area. Thus, while the SiO₂ film (hard mask film) 13 at the center area of the opening is etched to be removed, the surface of the SiN film used for forming the upper surface protection film 12 is exposed for a predetermined period of time in the peripheral area. While the SiN film, exposed for the predetermined period of time, may be slightly etched, the conditions of selectively etching the SiO₂ film (hard mask film) 13 are selected so that the film thickness of the etched SiN film at least falls in the range of 20 to 30 nm

The SiO₂ film (hard mask film) 13 can be selectively etched under the conditions of CF₄ gas flow rate=140 sccm, pressure of 6.6 [Pa], source power of 1200 W, and substrate bias power of 700 W, to maintain high selectivity to the SiCN film and the SiN film.

When the selective etching of the SiO₂ film (hard mask film) 13 used as the hard mask is completed, the stacked structure illustrated in FIG. 12D, including the upper surface protection film 12, the second upper electrode 11, the first upper electrode 10, the solid electrolyte film 9, and the titanium oxide film 8 that have been patterned, is formed in the opening area where the variable resistance element is formed. An angle formed between the side wall surface of the stacked structure and the upper surface of the insulating barrier film 7 in the lower layer is approximately 90°.

(Step B5)

As illustrated in FIG. 12E, step B5 is a step of depositing a protective insulation film 14 for covering the upper and side wall surfaces of the stacked structure illustrated including the upper surface protection film 12, the second upper electrode 11, the first upper electrode 10, the solid electrolyte film 9, and the titanium oxide film 8 that have been patterned, as well as the upper surfaces of the insulating barrier film 7 exposed in the periphery. A SiN film having a film thickness of 30 nm is used as the protective insulation film 14 for example.

The protective insulation film 14 is deposited by the isotropic depositing process to cover the upper and side wall surfaces of the stacked structure as well as the upper surfaces of the insulating barrier film 7 exposed therearound with a uniform film thickness. For example, the SiN film having a film thickness of 30 nm used as the protective insulation film 14 can be formed by plasma-enhanced CVD with SiH₄ and N₂ as raw material gas at a substrate temperature of 200° C. and by using high density plasma. Because no reducing gas such as NH₃ and H₂ is used, a reaction where H acts on oxygen (O) in the “porous polymer film” formed of the porous polymer mainly composed of silicon, oxygen, and carbon used as the solid electrolyte film 9 to be converted into H₂O can be prevented from occurring in a film forming gas stabilization step immediately before the film is formed.

The SiN film used as the protective insulation film 14 has high adhesiveness to the SiCN film used as the insulating barrier film 7 and the SiN film used as the upper surface protection film 12. Specifically, Si—N bond is achieved in the boundary between the SiCN film used as the insulating barrier film 7 and the SiN film deposited on the surface of the SiCN film, where by the films are integrated. The Si—N bond is also achieved in the boundary between the SiN film used as the upper surface protection film 12 and the SiN film deposited on an end surface of the SiCN film, where by the films are integrated.

Thus, the protective insulation film 14 covering the side wall surface of the stacked structure is integrated with the SiCN film used as the insulating barrier film 7 and the SiN film used as the upper surface protection film 12. Thus, the entrance of moisture and oxygen and desorption of oxygen to and from the side wall surface of the stacked structure can be effectively prevented. Thus, the yield and the reliability of the variable resistance element formed in the end can be improved.

(Step B6)

As illustrated in FIG. 12F, step B6 is a step of removing the SiN film covering the upper surface of the upper surface protection film 12 as well as the upper surface of the insulating barrier film 7 at the periphery of the stacked structure, while leaving the protective insulation film 14 covering the side wall surface of the stacked structure.

In the process, the anisotropic dry etching is employed so that the SiN film covering the upper surface of the upper surface protection film 12 and the upper surface of the insulating barrier film 7 at the periphery of the stacked structure are selectively etched with the etching of the SiN film covering the side wall surface of the stacked structure not proceeding. The anisotropic dry etching on the SiN film covering the upper surface of the upper surface protection film 12 and the upper surface of the insulating barrier film 7 at the periphery of the stacked structure can be performed by using the parallel-plate dry etching apparatus and under the conditions of CF₄/Ar gas flow rate=25/50 sccm, pressure of 0.53 [Pa], source power of 400 W, and substrate bias power of 90 W.

The SiN film covering the upper surface of the upper surface protection film 12 and the upper surface of the insulating barrier film 7 at the periphery of the stacked structure can be selectively etched back by employing “anisotropic etch back” process instead of the “anisotropic dry etching” so that the SiN film covering the side wall surface of the stacked structure remains.

For example, the etch back can be performed by introducing Ar gas into a growth reactor by using a plasma-enhanced CVD apparatus, and applying substrate bias. Here, when the conditions with which the “anisotropic etch back” proceeds can be set, the SiN film covering the upper surface of the upper surface protection film 12 and the upper surface of the insulating barrier film 7 at the periphery of the stacked structure can be selectively etched back so that the SiN film covering the side wall surface of the stacked structure remains.

In step B7 described later, after the SiN film, except for the SiN film covering the side wall surface of the stacked structure, has been removed, the SiO₂ film used for forming the second interlayer insulation film is deposited by plasma-enhanced CVD. When the “anisotropic etch back” process can be performed by introducing Ar gas into a growth reactor by using a plasma-enhanced CVD apparatus, and applying substrate bias, a state in FIG. 12F can be achieved by performing the “anisotropic etch back” process before the SiO₂ film is deposited. Here, a dedicated “parallel-plate dry etching apparatus” used for “anisotropic dry etching” step in step B6 needs not to be purchased, whereby an attempt to reduce a cost for manufacturing facility required for forming the variable resistance element can be facilitated. Furthermore, an attempt to reduce a product cost of the semiconductor device incorporating the variable resistance element can be facilitated.

(Step B7)

As illustrated in FIG. 12G, step B7 is a step of forming a second interlayer insulation film 15 that covers the upper surface protection film 12 of the stacked structure, the protective insulation film 14 that covers the side wall surface of the stacked structure, and the upper surfaces of the insulating barrier film 7 at the periphery of the stacked structure, and provided with planarization processing. The insulating barrier film 7 is also used as the first interlayer insulation film and the second interlayer insulation film 15 is in direct contact with the first interlayer insulation film (insulating barrier film 7).

In the variable resistance element of the fifth mode, a SiN film is used for forming the upper surface protection film 12 of the stacked structure and the protective insulation film 14 that covers the side wall surface of the stacked structure, a SiCN film is used for forming the first interlayer insulation film (insulating barrier film 7), and a silicon oxide film (SiO₂) film is used for forming the second interlayer insulation film 15.

The silicon oxide film is deposited by plasma-enhanced CVD as an isotropic deposition process to cover the upper surface protection film 12 of the stacked structure, the protective insulation film 14 that covers the side wall surface of the stacked structure, and the upper surfaces of the insulating barrier film 7 at the periphery of the stacked structure. A height difference Δh₁ of (2.0 nm+5 nm+10 nm+20 nm+30 nm)=67.0 nm is provided between an outer edge portion of the stacked structure formed in the upper surface of the insulating barrier film 7 and the upper surface of the insulating barrier film 7. The center portion of the stacked structure formed in the opening has a height Δh₂ of (2.0 nm+5 nm+10 nm+20 nm+30 nm−30 nm)=37.0 nm, with the upper surface of the insulating barrier film 7 as a reference. The film thickness of the silicon oxide film deposited on the center and the outer edge portions of the stacked structure that are at different levels, as well as on the upper surfaces of the first interlayer insulation film (insulating barrier film 7) in the periphery of the stacked structure, is selected to be at least five times as large as the height difference Δh₁, that is, about 450 nm for example. Here, as the film thickness of the deposited film increases, the height difference is gradually offset, whereby the difference in height (height difference) remaining on the upper surface of the deposited silicon oxide film is reduced. Still, the planarization is not completed yet.

Thus, planarization processing, such as, for example polishing processing using CMP, is performed on the surface of the deposited silicon oxide film.

When the silicon oxide film having a film thickness of about 450 nm is deposited by using plasma-enhanced CVD, for example, the condition used in step B3 for depositing the SiO₂ film (hard mask film) 13 can be employed.

In the planarization processing, such as, for example polishing processing using CMP, performed on the surface of the deposited silicon oxide film, a polishing amount on the silicon oxide film having a film thickness of about 450 nm is set to be 300 nm, so that the film thickness of the silicon oxide film after the polishing processing can be adjusted to 150 nm in the upper surface portion of the first interlayer insulation film (insulating barrier film 7).

In the polishing processing using CMP for the silicon oxide film, a generally used colloidal silica or ceria slurry can be used as an abrasive for the polishing.

(Step B8)

As illustrated in FIG. 12H, step B8 is a step of forming a third interlayer insulation film 16 and a fourth interlayer insulation film 17 on the upper surface of the second interlayer insulation film 15 formed of the silicon oxide film provided with the planarization processing.

In the variable resistance element of the fifth mode, a silicone oxide (SiO₂) film having a film thickness of 150 nm is used for the second interlayer insulation film 15. A SiOC film film having a film thickness of 150 nm is used for the third interlayer insulation film 16, and a SiO₂ film having a film thickness of 100 nm is used for the fourth interlayer insulation film 17.

The SiOC film used for forming the third interlayer insulation film 16 and the SiO₂ film used for forming the fourth interlayer insulation film 17 can both be deposited by plasma-enhanced CVD.

When the SiOC film is deposited by plasma-enhanced CVD, deposition conditions disclosed in Japanese Patent Application Laid-Open No. 2004-221275 may be employed. When the SiO₂ film is deposited by plasma-enhanced CVD, the conditions used for depositing the SiO₂ film (hard mask film) 13 in step B3 can be used.

(Step B9)

As illustrated in FIG. 12I, step B9 is a step of forming a “second wiring” 18a and a “second wiring” 18b that correspond to the wiring layer in the upper layer and formed in the third interlayer insulation film 16 stacked on the second interlayer insulation film 15 and in the fourth interlayer insulation film 17, forming a “plug” 19a integrated with the “second wiring” 18a and a “plug” 19b integrated with the “second wiring” 18b that are formed in the second interlayer insulation film 15, and forming a second insulating barrier film (fifth interlayer insulation film) that covers the “second wiring” 18a, the “second wiring” 18b, and the upper surface of the fourth interlayer insulation film 17 and a sixth interlayer insulation film stacked on the fifth interlayer insulation film.

The “plug” 19a integrated with the “second wiring” 18a is in contact with the upper surface of the second upper electrode 11 through the opening formed in the upper surface protection film 12. Thus, the “plug” 19a electrically connects between the “second wiring” 18a and the first electrode that serves as the “second electrode” in the variable resistance element.

The “plug” 19b integrated with the “second wiring” 18b is in contact with the upper surface of the metal (copper wiring) 5b of the “first wiring” corresponding to the wiring layer in the lower layer through the opening formed in the first interlayer insulation film (insulating barrier film 7). Thus, the “plug” 19b electrically connects between the “second wiring” 18b and the “first wiring”.

The “plug” 19a integrated with the “second wiring” 18a and the “plug” 19b integrated with the “second wiring” 18b are formed by a via first method in a dual damascene method.

First, a resist mask is formed on the upper surface of the fourth interlayer insulation film 17. The resist mask has an opening corresponding to a hole shape of a bottom surface of a via hole used for forming the “plug” 19a at a position right above a center portion of the upper surface protection film 12. The resist mask also has an opening corresponding to a hole shape of a bottom surface of a via hole used for forming the “plug” 19b at a position right above a center portion of the metal (copper wiring) 5b of the “first wiring” corresponding to the wiring layer in the lower layer. With the resist mask, anisotropic etching is sequentially performed on the fourth interlayer insulation film 17, the third interlayer insulation film 16, and the second interlayer insulation film 15 by dry etching. Thus, the via holes are formed that penetrate through the fourth interlayer insulation film 17 and the third interlayer insulation film 16, and the second interlayer insulation film 15 to reach the upper surface of the upper surface protection film 12 and the upper surface of the first interlayer insulation film (insulating barrier film 7) covering the surface of the metal (copper wiring) 5b of the “first wiring”.

After the resist mask used for forming the via holes are removed, a resist mask is formed on the upper surface of the fourth interlayer insulation film 17. The resist mask has an opening corresponding to the a pattern of the wiring trench for forming the “second wiring” 18a and an opening corresponding to the a pattern of the wiring trench for forming the “second wiring” 18b. With the resist mask, the anisotropic etching is sequentially performed on the fourth interlayer insulation film 17 and the third interlayer insulation film 16 by gradual dry etching. In the “gradual dry etching”, conditions providing selectivity to the SiO₂ film are selected as conditions for etching the SiOC film forming the third interlayer insulation film 16. As a result, the second interlayer insulation film 15 formed of the SiO₂ film functions as an etching stopper layer, in the step of etching the SiOC film forming the third interlayer insulation film 16. In a step of etching the SiOC film forming the third interlayer insulation film 16, side etching on the side wall surface of the fourth interlayer insulation film 17 formed of the SiO₂ film is prevented from proceeding. As a result, the wiring trench for forming the “second wiring” 18a and the wiring trench for forming the “second wiring” 18b are formed by the “gradual dry etching” on the fourth interlayer insulation film 17 and the third interlayer insulation film 16.

The resist mask, used for forming the wiring trenches, is removed. Then, by selecting conditions providing selectivity to the SiOC film and the SiO₂ film, dry etching is performed on the upper surface protection film 12 formed of the SiN film exposed on the bottom of the via holes and the first interlayer insulation film (insulating barrier film 7) formed of the SiCN film. Thus, the upper surface of the second upper electrode 11 and the surface of the metal (copper wiring) 5b of the “first wiring” are exposed from the bottom of the via holes.

Metal is embedded in the via holes integrated with the formed wiring trenches with the barrier metal in between, whereby the “plug” 19a integrated with the “second wiring” 18a and the “plug” 19b integrated with the “second wiring” 18b are formed. As the metal material used for forming the “plug” 19a integrated with the “second wiring” 18a and the “plug” 19b integrated with the “second wiring” 18b corresponding to the wiring layer in the upper layer, a metal material mainly composed of copper, such as copper for example, is used. The barrier metal prevents the diffusion of the copper. Thus, a stacked structure of TaN (film thickness of 5 nm)/Ta (film thickness of 5 nm) is used as the barrier metal.

The barrier metal formed of the stacked structure of TaN (film thickness of 5 nm)/Ta (film thickness of 5 nm) covers the side wall and the bottom portion of the via hole integrated with the wiring trench at a uniform film thickness. Thus, a deposition film formed of the stacked structure is formed on the side wall and the bottom portion of the via hole integrated with the wiring trench by isotropic depositing such as, for example, RF sputtering. Copper used as the metal uses the barrier metal 6 as a base layer, and is formed to be buried in the via hole integrated with the wiring trench by plating for example. Then, the stacked structure TaN (film thickness of 5 nm)/Ta (film thickness of 5 nm) formed on the upper surface of the fourth interlayer insulation film 17 is removed by CMP (Chemical-Mechanical Polishing) for example, whereby the upper surface of the “second wiring” formed in the wiring trench is planarized.

Then, the second insulating barrier film (fifth interlayer insulation film) that covers the upper surface of the “second wiring” and the upper surface of the fourth interlayer insulation film 17 is formed. The second insulating barrier film (fifth interlayer insulation film) prevents the diffusion of copper used as the metal of the “second wiring”. Thus, a SiCN film or a SiN film having a film thickness of 30 nm is selected for example as “insulating material used for forming the second insulating barrier film (fifth interlayer insulation film)”.

A SiO₂ film of a SiOC film is selected as the “insulating material used for forming the sixth interlayer insulation film” stacked on the second insulating barrier film (fifth interlayer insulation film)”.

The SiCN film or the SiN film used for forming the second insulating barrier film (fifth interlayer insulation film), and the SiO₂ film or the SiOC film used for forming the sixth interlayer insulation film may each be deposited by plasma-enhanced CVD.

The method for forming a protective insulation film employed in the variable resistance element according to the present invention can be checked in the state after the manufacturing. Specifically, the cross section of the device of a product employing the variable resistance element is observed by TEM, to check that the variable resistance element is formed in the multi-layered wiring layer. Furthermore, the TEM observation on the cross section is further performed to check that the protective insulation film is formed on the side surface of the variable resistance film of the electrode forming the variable resistance element. Furthermore, it is checked that the protective insulation film is not extending the horizontal direction, and is not used as the interlayer insulation film. By performing composition analysis such as EDX (Energy Dispersive X-ray Spectroscopy) and EELS (Electron Energy-Loss Spectroscopy), in addition to TEM, the insulating material used as the protective insulation film can be checked.

Specifically, when the variable resistance element formed on the copper wiring is a switching element using the variable resistance film formed of the solid electrolyte, whether the solid electrolyte film that functions as the “ion conducting layer” is a film including oxygen or carbon can be determined. When the variable resistance film forming the variable resistance element is a phase-change film, or the variable resistance element uses a magnetic material, whether the material described in this specification is used is determined by composition analysis on the element cross section. Furthermore, when checking that the protective insulation film is formed on the side surface of the stacked structure forming the variable resistance element and that the protective insulation film is a SiN film, the composition analysis is preferably performed as an area analysis. Whether the first interlayer insulation film and the second interlayer insulation film positioned above the first interlayer insulation film are provided and are in direct contact with each other can be determined from the cross sectional structure.

In the preferred exemplary embodiments and modes, the present invention is described in detail for a case of forming a ReRAM using “copper filament precipitating variable resistance element” employing the solid electrolyte layer as the variable resistance film and an oxygen-deficit ReRAM using the variable resistance film formed of metal oxides. The present invention may be applied to a variable resistance element employing a film other than the solid electrolyte and the metal oxides as the variable resistance film may be used instead of the configuration described above. Specifically, the present invention may be applied to a mode of forming a MRAM or a spin element using the variable resistance element, or a PRAM employing a phase-change variable resistance layer (GST) for example.

While the preferable exemplary embodiments and modes are illustrated to describe variable resistance elements and a method for producing a variable resistance element, the exemplary embodiments and modes are selected by way of example for describing the technical principle of the present invention in detail, and the technical scope of the present invention is not intended to limited to these specific examples.

For example, the foregoing describes in detail techniques applicable to semiconductor devices including CMOS circuits, the technical field of which served as a background for the development of the present invention made by the inventors, and also describes exemplary embodiments in which a variable resistance element is formed above a copper wiring on a semiconductor substrate. However, the technical idea of the present invention is not limited to these “exemplary embodiments in which a variable resistance element is formed above a copper wiring on a semiconductor substrate”. The technical idea of the present invention is, for example, also applicable to semiconductor products including memory circuits such as a DRAM (Dynamic RAM), an SRAM (Static RAM), a flash memory, an FRAM (Ferro Electric RAM), an MRAM (Magnetic RAM), a variable resistance memory, and a bipolar transistor; semiconductor products including logic circuits such as a microprocessor; and copper wirings in boards or packages on which these products are mounted in combination.

The multi-layered wiring layers provided inside the variable resistance elements according to the present invention are applicable to the joining of electronic circuit devices, optical circuit devices, quantum circuit devices, micro machines, MEMS (Micro Electro Mechanical Systems), and the like to semiconductor devices. While examples of the use of the switching function of the variable resistance element according to the present invention have been mainly described, the variable resistance element according to the present invention can be used for memory elements, for example, using both the non-volatile and variable resistance properties.

While the representative exemplary embodiments and modes have been illustrated to describe the present invention, the technical scope of the present invention is not limited to the representative exemplary embodiments and modes. Various modifications that can be appreciated by the skilled person in the art can be made in putting the present invention into practice within the scope (technical scope) of the present invention.

While the exemplary embodiments (and examples) are referred to in order to describe the present invention, the present invention is not limited to the exemplary embodiments (and examples) described above. Various modifications that can be appreciated by the skilled person in the art can be made in the configurations and details of the present invention within the scope of the present invention.

The present application claims priority to Japanese Patent Application No. 2012-181724 filed on Aug. 20, 2012, the entirety of which is herein incorporated by reference.

### INDUSTRIAL APPLICABILITY

The variable resistance elements according to the present invention are applicable to non-volatile switching elements provided in multi-layered wiring layers in semiconductor devices.

1. A variable resistance element provided in a wiring layer on a semiconductor substrate,
the wiring layer including a first interlayer insulation film and a second interlayer insulation film positioned above the first interlayer insulation film,
the variable resistance element comprising:
a variable resistance film formed on the first interlayer insulation film; and
a first electrode formed in contact with an upper surface of the variable resistance film,
a side surface of the variable resistance element including the variable resistance film and the first electrode being provided with a protective insulation film that covers at least a side surface of the variable resistance film,
at least the protective insulation film provided to the side surface of the variable resistance element being covered with a second interlayer insulation film,
the second interlayer insulation film and the first interlayer insulation film being directly in contact with each other.

2. The variable resistance element according to claim 1, wherein the protective insulation film is formed of a SiN film.

3. The variable resistance element according to claim 1, wherein a wiring forming the wiring layer is a copper wiring, and
the first interlayer insulation film is in contact with an upper surface of a copper wiring in a lower layer.

4. The variable resistance element according to claim 3, wherein the first interlayer insulation film has an opening, and
the variable resistance film in the variable resistance element is in contact with the upper surface of the copper wiring in the lower layer through the opening.

5. The variable resistance element according to claim 4, wherein the first interlayer insulation film is formed of a SiN film or a SiCN film.

6. The variable resistance element according to claim 1, wherein the first electrode is formed of a metal containing Ru as a main component, and
the variable resistance film is a film formed of a solid electrolyte.

7. The variable resistance element according to claim 6, wherein the film formed of a solid electrolyte is the porous film.

8. The variable resistance element according to claim 1, wherein the variable resistance film contains an oxide.

9. The variable resistance element according to claim 1, wherein the second interlayer insulation film is a SiO₂ film.

10. The variable resistance element according to claim 1, wherein an upper surface of the first electrode is provided with an upper surface protection film, and
the protective insulation film covers side surfaces of the variable resistance film, the first electrode, and the upper surface protection film.

11. The variable resistance element according to claim 2, wherein the variable resistance film contains an oxide.

12. The variable resistance element according to claim 2, wherein an upper surface of the first electrode is provided with an upper surface protection film, and
the protective insulation film covers side surfaces of the variable resistance film, the first electrode, and the upper surface protection film.
